(19) United States
(12) Patent Application Publication
(10) Pub. No.: US 2025/0107359 A1
(43) Pub. Date: Mar. 27, 2025

(54) DISPLAY APPARATUS AND METHOD OF MANUFACTURING THE SAME

(71) Applicant: Samsung Display Co., Ltd., Yongin-si (KR)

(72) Inventors: Kiho Bang, Yongin-si (KR); Sungho Kim, Yongin-si (KR); Wonsuk Choi, Yongin-si (KR)

(73) Assignee: Samsung Display Co., Ltd., Yongin-si (KR)

(21) Appl. No.: 18/627,776

(22) Filed: Apr. 5, 2024

(30) Foreign Application Priority Data
Sep. 22, 2023 (KR) 10-2023-0127293

(51) Int. Cl. H10K 59/131; H10K 59/12; H10K 59/122; H10K 59/40; H10K 59/80

(52) U.S. Cl. CPC H10K 59/131; H10K 59/1201; H10K 59/122; H10K 59/40; H10K 59/873

(57) ABSTRACT

A display apparatus includes a substrate comprising a display area, a bending area spaced apart from the display area in a first direction, and a first peripheral area disposed between the display area and the bending area, a plurality of emission layers disposed in the display area, an opposite electrode disposed on the plurality of emission layers and overlapping the display area and the first peripheral area, and an encapsulation layer disposed on the opposite electrode and overlapping the display area and the first peripheral area. A first edge portion of the opposite electrode and a first edge portion of the encapsulation layer are coplanar with each other in the first peripheral area.

### CROSS-REFERENCE TO RELATED APPLICATION(S)

This application claims priority to and benefits of Korean Patent Application No. 10-2023-0127293 under 35 U.S.C. § 119, filed on Sep. 22, 2023, in the Korean Intellectual Property Office, the entire contents of which are incorporated herein by reference.

### BACKGROUND

### 1. Technical Field

One or more embodiments relate to display apparatuses and methods of manufacturing the display apparatuses, and more particularly, to a display apparatus including an organic light-emitting diode and a method of manufacturing the display apparatus.

### 2. Description of the Related Art

Display apparatuses include display elements and display an image. Such display apparatuses may be implemented in various devices, for example, in various electronic devices such as smartphones, digital cameras, laptop computers, navigation devices, or smart televisions. The display apparatuses may have a touch screen function for user convenience. For example, display apparatuses may detect a user's touch input and display an image corresponding to the user's touch input.

### SUMMARY

A display apparatus may include an integrated circuit chip for processing a touch input, display information, etc. The integrated circuit chip may be disposed on a substrate of the display apparatus. The substrate of the display apparatus may be bendable. In the display apparatus, a portion of the substrate may be bent to be disposed on a rear surface of the display apparatus so that an area where the integrated circuit chip and the like are arranged is not visible to a user.

Some layers of the display apparatus need to be not disposed in an area where the substrate is bent. During a manufacturing process of the display apparatus, for example, a deposition process, an open mask is used to cover only a partial area of the display apparatus. The open mask may generally have a straight structure.

In case that display apparatuses are manufactured, multiple display apparatuses are manufactured simultaneously on one mother substrate. For example, in order to use a straight open mask, there is no choice but to manufacture display apparatuses of the same specifications on the same mother substrate. This leads to an increase in an unused area among the area of the mother substrate, particularly, an outer area.

Additional aspects will be set forth in part in the description which follows and, in part, will be apparent from the description, or may be learned by practice of the presented embodiments.

According to one or more embodiments, a display apparatus may include a substrate including a display area, a bending area spaced apart from the display area in a first direction, and a first peripheral area disposed between the display area and the bending area, a plurality of emission layers disposed in the display area, an opposite electrode disposed on the plurality of emission layers and overlapping the display area and the first peripheral area, and an encapsulation layer disposed on the opposite electrode and overlapping the display area and the first peripheral area. A first edge portion of the opposite electrode and a first edge portion of the encapsulation layer are coplanar with each other in the first peripheral area.

The display apparatus may further include a common layer disposed above or below the plurality of emission layers.

The common layer may overlap the display area and the first peripheral area, and a first edge portion of the common layer, the first edge portion of the opposite electrode and the first edge portion of the encapsulation layer may be coplanar with each other in the first peripheral area.

The substrate may include a second peripheral area partially surrounding the display area, the opposite electrode and the encapsulation layer may overlap the display area and the second peripheral area, a second edge portion of the opposite electrode and a second edge portion of the encapsulation layer are disposed in the second peripheral area, the common layer may overlap the display area, and a second edge portion of the common layer may be disposed between the display area and the second edge portion of the opposite electrode.

The substrate may further include a pad area, the bending area may be disposed between the pad area and the display area, the opposite electrode may include a first portion overlapping the first peripheral area and a second portion overlapping the pad area, and the encapsulation layer may include a first portion overlapping the first peripheral area and a second portion overlapping the pad area.

The first portion of the opposite electrode and the second portion of the opposite electrode may be spaced apart from each other, and the first portion of the encapsulation layer and the second portion of the encapsulation layer may be spaced apart from each other.

The display apparatus may further include a touch insulating layer disposed on the encapsulation layer and overlapping the display area and the first peripheral area, and a first connection line disposed on the touch insulating layer and overlapping the first peripheral area. A first edge portion of the touch insulating layer may be disposed in the first peripheral area, and the first connection line may cover the first edge portion of the touch insulating layer.

The display apparatus may further include a second connection line interposed between the substrate and the touch insulating layer and overlapping the first peripheral area and the bending area. The second connection line may overlap the first edge portion of the touch insulating layer, and the first connection line and the second connection line may be in direct contact with the first peripheral area.

The substrate may include a second peripheral area partially surrounding the display area, and the display apparatus may further include a bank layer between the substrate and the opposite electrode, and a sidewall disposed on the bank layer in the second peripheral area.

The sidewall may include a first layer in direct contact with the bank layer, and a second layer disposed on the first layer and having a width that is greater than a width of an upper surface of the first layer, and the first layer and the second layer may include materials having different etch selectivities.

The display apparatus may further include a capping layer interposed between the opposite electrode and the encapsulation layer and overlapping the display area and the first peripheral area. A first edge portion of the capping layer, the first edge portion of the opposite electrode and the first edge portion of the encapsulation layer may be coplanar with each other in the first peripheral area.

According to one or more embodiments, a method of manufacturing a display apparatus may include preparing a substrate comprising a display area, a bending area spaced apart from the display area in a first direction, a pad area disposed in the first direction from the bending area, and a first peripheral area disposed between the display area and the bending area, arranging a plurality of emission layers spaced apart from each other in the display area, disposing an opposite electrode on the plurality of emission layers, disposing an encapsulation layer on the opposite electrode, and removing a portion of each of the opposite electrode and the encapsulation layer that overlap the bending area. After the removing of the portion of each of the opposite electrode and the encapsulation layer, a first edge portion of the opposite electrode and a first edge portion of the encapsulation layer may be coplanar with each other in the first peripheral area.

The opposite electrode may include a first portion overlapping the first peripheral area and a second portion overlapping the pad area and being spaced apart from the first portion of the opposite electrode. The encapsulation layer may include a first portion overlapping the first peripheral area and a second portion overlapping the pad area and being spaced apart from the first portion of the encapsulation layer. The method may further include removing the second portion of the opposite electrode and the second portion of the encapsulation layer.

The method may further include disposing a common layer that is below the opposite electrode and overlaps the plurality of emission layers, and removing a portion of the common layer that overlaps the bending area. After the removing of the portion of the common layer, a first edge portion of the common layer, the first edge portion of the opposite electrode and the first edge portion of the encapsulation layer may be coplanar with each other in the first peripheral area.

The method may further include disposing a common layer that is below the opposite electrode and overlaps the plurality of emission layers. The substrate may include a second peripheral area partially surrounding the display area, the opposite electrode and the encapsulation layer may overlap the display area and the second peripheral area, a second edge portion of the opposite electrode and a second edge portion of the encapsulation layer may be disposed in the second peripheral area, the common layer may overlap the display area, and a second edge portion of the common layer may be disposed between the display area and the second edge portion of the opposite electrode.

The method may further include disposing a touch insulating layer on the encapsulation layer, and removing a portion of the touch insulating layer overlapping the bending area and a portion of the touch insulating layer overlapping the pad area. After the removing of the portion of the touch insulating layer, a first edge portion of the touch insulating layer may be disposed in the first peripheral area.

The method may further include disposing a first connection line on the touch insulating layer to cover the first edge portion of the touch insulating layer.

The substrate may include a second peripheral area partially surrounding the display area, and the method may further include forming a bank layer including a plurality of openings respectively overlapping the plurality of emission layers on the substrate, and forming a sidewall on the bank layer in the second peripheral area.

The forming of the sidewall may include forming a first layer on the bank layer, and forming a second layer on the first layer, the first layer and the second layer may include materials having different etch selectivities, and a width of an upper surface of the second layer may be greater than a width of the second layer.

The method may further include disposing a capping layer interposed between the encapsulation layer and the opposite electrode, and removing a portion of the capping layer that overlaps the bending area. After the removing of the portion of the capping layer, a first edge portion of the capping layer, the first edge portion of the opposite electrode and the first edge portion of the encapsulation layer may be coplanar with each other in the first peripheral area.

### BRIEF DESCRIPTION OF THE DRAWINGS

The above and other aspects, features, and advantages of certain embodiments will be more apparent from the following description taken in conjunction with the accompanying drawings, in which:

FIG. 1 is a schematic plan view of a display apparatus according to an embodiment;

FIG. 2 is a schematic side view of the display apparatus including components shown in FIG. 1;

FIG. 3 is a schematic cross-sectional view of a portion of a display area of the display apparatus according to an embodiment;

FIG. 4A is a schematic cross-sectional view of a portion of the display apparatus according to an embodiment;

FIG. 4B is a schematic plan view of the embodiment shown in FIG. 4A;

FIG. 5A is a schematic cross-sectional view of a portion of the display apparatus according to another embodiment;

FIG. 5B is a schematic plan view of the embodiment shown in FIG. 5A;

FIGS. 6A, 6B, 6C, 6D, 6E, and 6F are schematic cross-sectional views illustrating a method of manufacturing a display apparatus, according to an embodiment;

FIGS. 7A, 7B, 7C, and 7D are schematic cross-sectional views illustrating a method of manufacturing a display apparatus, according to another embodiment;

FIG. 8 is a schematic cross-sectional view of a portion of a display apparatus according to an embodiment;

FIG. 9 is a magnified schematic cross-sectional view of region IX of FIG. 8; and

FIGS. 10A, 10B, 10C, and 10D are schematic cross-sectional views illustrating a method of manufacturing the embodiment of FIG. 9.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction X, the axis of the second direction Y, and the axis of the third direction Z are not limited to three axes of a rectangular coordinate system, such as the X, Y, and Z-axes, and may be interpreted in a broader sense. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

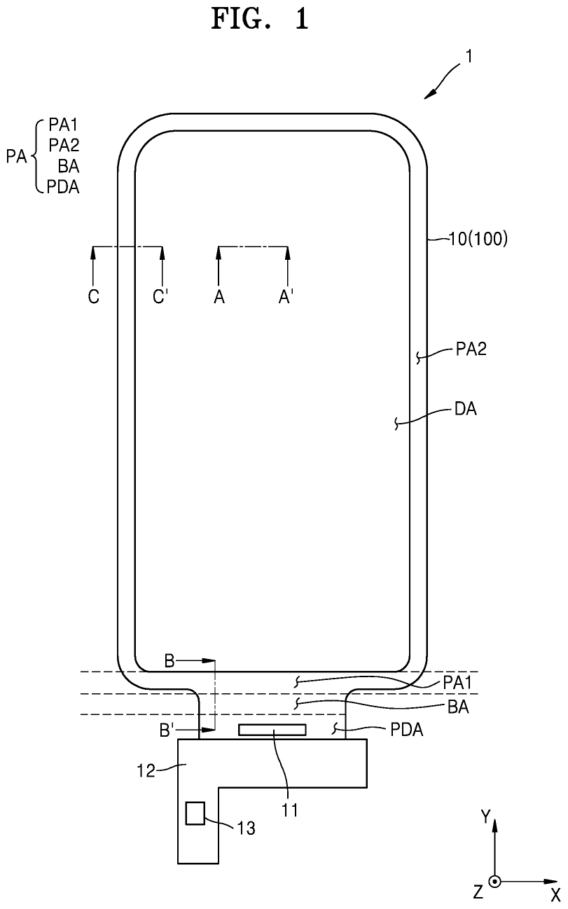

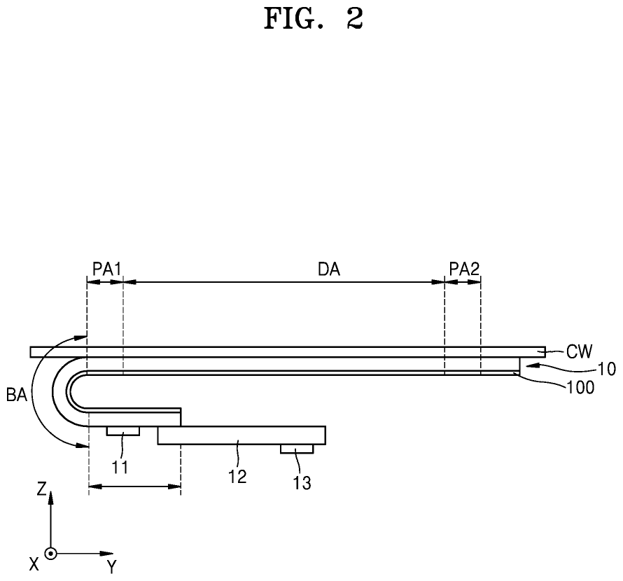

FIG. 1 is a schematic plan view of a display apparatus 1 according to an embodiment. FIG. 2 is a schematic side view of the display apparatus 1 including components shown in FIG. 1.

In FIG. 2, as a substrate is flexible, a display panel 10 may have a bent shape in a bending area BA. For convenience of explanation, FIG. 1 shows the display panel 10 in an unbent state.

Referring to FIGS. 1 and 2, the display apparatus 1 according to an embodiment may display a moving picture or a still image, and thus may be used as the display screens of various products such as not only portable electronic apparatuses, such as mobile phones, smartphones, tablet personal computers (PCs), mobile communication terminals, electronic notebooks, electronic books, portable multimedia players (PMPs), navigation devices, and ultra mobile PCs (UMPCs) but also televisions, notebooks, monitors, advertisement panels, and internet of things (IOT) devices. The display apparatus 1 may be used in wearable devices such as smart watches, watch phones, glasses-type displays, and head mounted displays (HMDs). The display apparatus 1 may be used as dashboards of automobiles, center information displays (CIDs) of the center fasciae or dashboards of automobiles, room mirror displays that replace the side mirrors of automobiles, and displays arranged on the rear sides of front seats to serve as entertainment devices for back seat passengers of automobiles.

For convenience of explanation, FIGS. 1 and 2 illustrate usage of a smartphone as the display apparatus 1. The display apparatus 1 may include a cover window (CW), the display panel 10, a display driving unit 11, a display circuit board 12, a sensor driving unit 13, etc. The display apparatus 1 may further include a bracket, a main circuit board, a battery, a lower cover, and the like.

The term “above” indicates a direction in which the cover window CW is disposed in relation to the display panel 10, namely, a positive Z-axis direction, and the term “below” indicates a negative Z-axis direction, which is an opposite direction to the direction in which the cover window CW is disposed in relation to the display panel 10.

The display apparatus 1 may have an approximately rectangular shape as shown in FIG. 1, when viewed in a direction perpendicular to its surface. For example, the display apparatus 1 may have an overall rectangular planar shape having shorter sides each extending in a positive X-axis direction and a negative X-axis direction and longer sides each extending in a positive Y-axis direction and a negative Y-axis direction, as shown in FIG. 1. Corners between the shorter sides in the positive X-axis direction and the negative X-axis direction and the longer sides in the positive Y-axis direction and the negative Y-axis direction may be rounded to have a certain curvature, or may have right angles. The planar shape of the display apparatus 1 is not limited to a rectangle, and may be any other polygonal shape, a circular shape, or an oval shape.

As shown in FIG. 2, the cover window CW may be disposed above the display panel 10 to cover an upper surface of the display panel 10. The cover window CW may function to protect the upper surface of the display panel 10.

The display panel 10 may be disposed below the cover window CW. The display panel 10 may overlap a transmissive portion of the cover window CW. The display panel 10 may include a substrate 100, and display elements disposed on the substrate 100.

The display panel 10 may display (or output) information that is processed by the display apparatus 1. For example, the display panel 10 may display execution screen information of an application being driven by the display device 1, or may display user interface (UI) and graphical user interface (GUI) information based on the execution screen information. The display panel 10 may include a display layer that displays an image, and a touch layer that senses a touch input of a user. Accordingly, the display panel 10 may function as one of input devices providing an input interface between the display apparatus 1 and a user, and function as one of output devices providing an output interface between the display apparatus 1 and the user.

The substrate 100 included in the display panel 10 may include an insulating material, such as glass, quartz, and polymer resin. The substrate 100 may be a rigid substrate or a flexible substrate that is bendable, foldable, or rollable. In FIG. 2, as the substrate 100 is flexible, the display panel 10 may have a bent shape in the bending area BA.

The substrate 100 may have a display area DA and a peripheral area PA outside the display area DA, and display elements may be disposed on the display area DA of the substrate 100.

In the peripheral area PA of the substrate 100, images may not be displayed. For example, the peripheral area PA may surround the display area DA. The peripheral area PA may be an area disposed between the edge portion of the display area DA and the edge portion of the display panel 10. In the display area DA, not only pixels but also scan lines, data lines, power lines, etc. connected (e.g., electrically connected) to the pixels may be arranged. In the peripheral area PA, a scan driving unit for applying scan signals to the scan lines, and fan out lines connecting the data lines to the display driving unit 11 may be disposed.

The display elements may include, for example, light-emitting elements. For example, the display panel 10 may be an organic light-emitting display panel using an organic light-emitting diode including an organic emission layer, a micro light-emitting diode (LED) display panel using a micro LED, a quantum dot light-emitting display panel using a quantum dot LED including a quantum dot emission layer, or an inorganic light-emitting display panel using an inorganic light-emitting element including an inorganic semiconductor.

The display panel 10 may be a rigid display panel having rigidity and thus may not be readily bent, or a flexible display panel having flexibility and may be readily bent, folded, or rolled. For example, the display panel 10 may be a foldable display panel, a curved display panel having a display surface at least a portion of which is bent, a bent display panel of which an area other than a display surface is bent, a rollable display panel, or a stretchable display panel.

The display panel 10 may be a transparent display panel. For example, the display panel 10 may have transparent characteristics, so that a user may see an object or a background arranged below the display panel 10 through the upper surface of the display panel 10. In another example, the display panel 10 may be a reflective display panel capable of reflecting an object or a background above the display panel 10.

As shown in FIG. 1, the display panel 10 may have the bending area BA on a side in the negative Y-axis direction, and, thus, the display panel 10 may be bent in the bending area BA as shown in FIG. 2. For example, for convenience of explanation, FIG. 1 shows the display panel 10 in an unbent state. As the display panel 10 is bent as described above, a pad area PDA may be disposed below another portion of the display panel 10 in the negative Z-axis direction.

The bending area BA and the pad area PDA may protrude from a side of the display panel 10 in the negative Y-axis direction. In FIGS. 1 and 2, a length of each of the bending area BA and the pad area PDA in the positive X-axis direction and the negative X-axis direction is less than a length of the display area DA in the positive X-axis direction and the negative X-axis direction. However, the disclosure is not limited thereto.

A portion of the peripheral area PA disposed between the bending area BA and the display area DA may be defined as a first peripheral area PA1. A length of the display panel 10 in the positive X-axis direction and the negative X-axis direction may decrease in the first peripheral area PA1. Although FIG. 1 illustrates that an edge portion of the display panel 10 in the first peripheral area PA1 is parallel to the positive X-axis direction and the negative X-axis direction, the disclosure is not limited thereto. According to another embodiment, the edge portion of the display panel 10 in the first peripheral area PA1 may extend diagonally with respect to the positive X-axis direction and the negative X-axis direction and the positive Y-axis direction and the negative Y-axis direction, and may have a curved shape. A second peripheral area PA2 may be disposed on a positive X-axis direction and a negative X-axis direction side and a positive Y-axis side of the display area DA to partially surround the display area DA.

As described above, the display panel 10 may be bent in the bending area BA, and, accordingly, the pad area PDA may overlap the display area DA in a thickness direction (e.g., Z-axis direction) of the display panel 10. In the pad area PDA, the display driving unit 11 and the display circuit board 12 may be arranged.

The display driving unit 11 may receive control signals and power supply voltages and generate and output signals and voltages for driving the display panel 10. The display driving unit 11 may be an integrated circuit (IC).

The display circuit board 12 may be electrically connected to the display panel 10. For example, the display circuit board 12 may be electrically connected to a pad portion on the substrate 100 by an anisotropic conductive film.

The display circuit board 12 may be a flexible printed circuit board (FPCB) that is bendable, a rigid printed circuit board (PCB) that has rigidity and thus is not readily bent, or a complex PCB including both a rigid PCB and an FPCB.

The sensor driving unit 13 may be disposed on the display circuit board 12. The sensor driving unit 13 may include an IC. The sensor driving unit 13 may be attached onto the display circuit board 12. The sensor driving unit 13 may be electrically connected to touch electrodes of the display panel 10 via the display circuit board 12.

A power supplier for supplying driving voltages for driving the pixels of the display panel 10, the scan driving unit, and the display driving unit 11 may be additionally arranged on the display circuit board 12. In another example, the power supplier may be integrated with the display driving unit 11. For example, the display driving unit 11 and the power supplier may be realized as an IC (e.g., a single IC).

The display circuit board 12 may be electrically connected to a main circuit board. The main circuit board may include, for example, a main processor including an IC, a camera device, a wireless communication unit, an input unit, an output unit, an interface unit, memory, and/or a power supplier.

For example, a panel lower cover may be disposed below the display panel 10. The panel lower cover may include at least one of a light absorption member for absorbing externally incident light, a cushion member for absorbing an external impact, and a heat dissipation member for efficiently dissipating heat of the display panel 10.

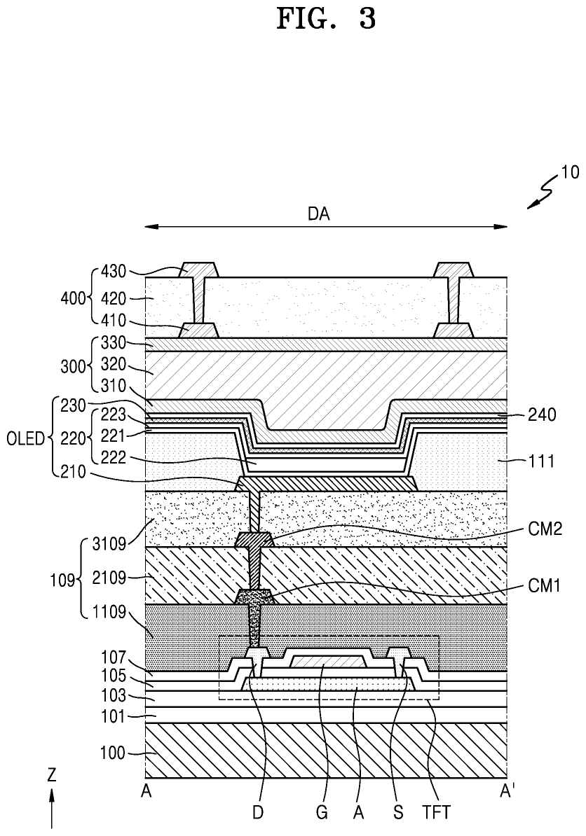

FIG. 3 is a schematic cross-sectional view of a portion of a display area DA of a display apparatus according to an embodiment. FIG. 3 may correspond to a cross-section of the display apparatus 1 taken along line A-A′ of FIG. 1.

Referring to FIG. 3, an organic light-emitting diode OLED may be disposed as a display element on the substrate 100. The organic light-emitting diode OLED may be electrically connected to a thin-film transistor TFT.

A barrier layer 101 and a buffer layer 103 may be arranged on the substrate 100. The barrier layer 101 and the buffer layer 103 may function to flatten and protect the upper surface of the substrate 100. The barrier layer 101 and the buffer layer 103 may include an inorganic insulating material such as silicon oxide (SiOₓ), silicon nitride (SiNₓ), and/or silicon oxynitride (SiOₓN_{y}), and may have a single-layer structure or a multi-layer structure of the above-described materials.

The thin-film transistor TFT may be disposed over the buffer layer 103. The thin-film transistor TFT may include an active layer A, a gate electrode G, a source electrode S, and a drain electrode D. The thin-film transistor TFT may be connected (e.g., electrically connected) to the organic light-emitting diode OLED and may drive the organic light-emitting diode OLED.

The active layer A may be disposed on the buffer layer 103, and may include a drain region overlapping (or connected to) the drain electrode D, a source region overlapping (or connected to) the source electrode S, and a channel region disposed between the drain region and the source region. The drain region and the source region may be regions doped with impurities (or dopants).

A gate insulating layer 105 may be disposed on the active layer A. The gate insulating layer 105 may include an inorganic material including oxide or nitride. For example, the gate insulating layer 105 may include at least one of silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), and zinc oxide (ZnO₂), and may have a single-layer structure or a multi-layer structure of the above-described materials.

The gate electrode G may be disposed on the gate insulating layer 105. At least a portion of the gate electrode GE may overlap the active layer A. For example, the gate electrode G may overlap the channel region of the active layer A. The gate electrode G may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may have a single layer structure or a multi-layer structure including the aforementioned materials.

An interlayer insulating layer 107 may be disposed to cover the gate electrode G. The interlayer insulating layer 107 may include an inorganic material including oxide or nitride. For example, the interlayer insulating layer 107 may include at least one of silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), and zinc oxide (ZnO₂), and may have a single-layer structure or a multi-layer structure of the above-described materials.

The gate insulating layer 105 and the interlayer insulating layer 107 may include contact holes that overlap the source and drain regions of the active layer A. The source electrode S and the drain electrode D may be disposed on the interlayer insulating layer 107. The source electrode S may be disposed to overlap the source region of the active layer A, and the drain electrode D may be disposed to overlap the drain region of the active layer A. The source electrode S and the drain electrode D may each be connected (e.g., electrically connected) to the active layer A via the respective contact holes formed in the gate insulating layer 105 and the interlayer insulating layer 107.

First, second, and third organic insulating layers 1109, 2109, and 3109 may be sequentially disposed on the interlayer insulating layer 107. The first, second, and third organic insulating layers 1109, 2109, and 3109 may include openings that overlap the drain electrode D. First and second connection metals CM1 and CM2 may be disposed on the first and second organic insulating layers 1109 and 2109, respectively. According to an embodiment, the first organic insulating layer 1109 may be disposed on the interlayer insulating layer 107 and may include an opening that overlaps the drain electrode D. The first connection metal CM1 may be disposed on the first organic insulating layer 1109 and may be connected (e.g., electrically connected) to the drain electrode D through the opening of the first organic insulating layer 1109. The second organic insulating layer 2109 may be disposed on the first organic insulating layer 1109 and may include an opening that overlaps the first connection metals CM1. The second connection metal CM2 may be disposed on the second organic insulating layer 2109 and may be connected (e.g., electrically connected) to the first connection metals CM1 through the opening of the second organic insulating layer 2109. The third organic insulating layer 3109 may be disposed on the second organic insulating layer 2109 and may include an opening that overlaps the second connection metals CM2.

The first and second connection metals CM1 and CM2 may include Al, Cu, and/or Ti, and may each be a multi-layer or single layer including the aforementioned materials.

The first, second, and third organic insulating layers 1109, 2109, and 3109 may include a commercial polymer such as benzocyclobutene (BCB), polyimide, hexamethyldisiloxane (HMDSO), polymethyl methacrylate (PMMA) or polystyrene (PS), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, or the like, and may each have a single layer structure or a multi-layer structure including the aforementioned materials.

A subpixel electrode 210 may be disposed on the third organic insulating layer 3109. The subpixel electrode 210 may be connected (e.g., electrically connected) to the second connection metal CM2 through the opening of the third organic insulating layer 3109. Accordingly, the subpixel electrode 210 may be electrically connected to the thin-film transistor TFT through the first and second connection metals CM1 and CM2 and the drain electrode D, and thus may receive a voltage.

The subpixel electrode 210 may include conductive oxide such as indium tin oxide (ITO), indium zinc oxide (IZO), zinc oxide (ZnO), indium oxide (In₂O₃), indium gallium oxide (IGO), or aluminum zinc oxide (AZO). The subpixel electrode 210 may include a reflection layer including silver (Ag), magnesium (Mg), aluminum (Al), platinum (Pt), palladium (Pd), gold (Au), nickel (Ni), neodymium (Nd), iridium (Ir), chromium (Cr), or a compound of these materials. The configuration and material of the subpixel electrode 210 are not limited to those described above, and various modifications may be made to the subpixel electrode 210.

A bank layer 111 may be disposed on the third organic insulating layer 3109. The bank layer 111 may cover an edge portion (or an edge area) of the subpixel electrode 210. For example, the bank layer 111 may have an opening to expose a portion of a center portion of the subpixel electrode 210. A size and shape of an emission region of the organic light-emitting diode OLED may be determined (or defined) by the opening of the bank layer 111.

An intermediate layer 220 may be disposed on the subpixel electrode 210. The intermediate layer 220 may include a first common layer 221 and a second common layer 223 disposed on the bank layer 111, and an emission layer 222 disposed in the opening of the bank layer 111. According to some embodiments, the first common layer 221 may be disposed on the bank layer 111, the emission layer 222 may be disposed on the first common layer 221 in the opening of the bank layer 111, and the second common layer 223 may be disposed on the first common layer 221 to cover the emission layer 222. For example, the emission layer 222 may be disposed in the opening of the bank layer 111 and interposed between the first and second common layers 221 and 223.

The emission layer 222 may include an organic emission layer including a low-molecular weight or high-molecular weight material. The first common layer 221 may include an electron transport layer (ETL) and/or an electron injection layer (EIL). The second common layer 223 may include a hole transport layer (HTL) and/or a hole electron injection layer (HIL). According to some embodiments, the first common layer 221 or the second common layer 223 may be omitted. According to some embodiments, the locations (or positions) of the first common layer 221 and the second common layer 223 may be interchanged.

An opposite electrode 230 may be disposed on the intermediate layer 220. For example, an opposite electrode may be disposed on the second common layer 223. The opposite electrode 230 may be arranged to cover the entirety of the intermediate layer 220. The opposite electrode 230 may include a conductive material having a low work function. For example, the opposite electrode 230 may include a transparent layer (or semi-transparent layer) including, for example, silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca) or an alloy of these materials. In another example, the opposite electrode 230 may further include a layer, such as ITO, IZO, ZnO, or In₂O₃, on the transparent layer (or semi-transparent layer) including any of the above-described materials.

A capping layer 240 may be disposed on the opposite electrode 230. The capping layer 240 may have a lower refractive index than the opposite electrode 230, and may improve luminescent efficiency by decreasing a percentage that light generated by the intermediate layer 220 is totally reflected and thus is not emitted to the outside.

The capping layer 240 may be an organic capping layer including an organic material, an inorganic capping layer including an inorganic material, or a complex capping layer including an organic material and an inorganic material. For example, the capping layer 240 may include a carbocyclic compound, a heterocyclic compound, an amine group-containing compound, porphine derivatives, phthalocyanine derivatives, naphthalocyanine derivatives, an alkali metal complex, an alkaline earth metal complex, or any combination thereof. In another example, the capping layer 240 may include an inorganic material such as zinc oxide (ZnO), titanium oxide (TiOₓ), zirconium oxide (ZrOₓ), nitrogen oxide (NO), niobium oxide (NbOₓ), tantalum oxide (TaOₓ), tin oxide (SnO₂), nickel oxide (NiOₓ), indium nitride (InN), and gallium nitride (GaN). The materials used to form the capping layer 240 are not limited thereto, and various other materials may be used.

An encapsulation layer 300 may be disposed on the capping layer 240. The encapsulation layer 300 may include at least one inorganic layer and at least one organic layer. According to an embodiment, the encapsulation layer 300 may include first and second inorganic encapsulation layers 310 and 330 and an organic encapsulation layer 320 between the first and second inorganic encapsulation layers 310 and 330. The first and second inorganic encapsulation layers 310 and 330 may include at least one inorganic insulating material such as silicon oxide (SiOₓ), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO₂). The organic encapsulation layer 320 may include a polymer-based material. Examples of the polymer-based material may include a silicon-based resin, an acryl-based resin, an epoxy-based resin, polyimide, and polyethylene.

An input sensing layer 400 may be disposed on the encapsulation layer 300. The input sensing layer 400 may include first and second touch electrodes 410 and 430 and a touch insulating layer 420. The first touch electrode 410 may be disposed on the encapsulation layer 300. For example, the first touch electrode 410 may be disposed on the second inorganic encapsulation layer 330. The touch insulating layer 420 and the second touch electrode 430 may be sequentially disposed on the first touch electrode 410.

The touch insulating layer 420 may include an organic insulating material. For example, the touch insulating layer 420 may include at least one inorganic insulating material selected from silicon oxide (SiOₓ), silicon nitride (SiNₓ), and silicon oxynitride (SiOₓN_{y}). The first and second touch electrodes 410 and 430 may be arranged in a specific pattern and may each include a metal layer. For example, the first and second touch electrodes 410 and 430 may be arranged so as not to overlap the emission area of the organic light-emitting diode OLED or not to overlap the emission layer 222. According to some embodiments, organic light-emitting diodes OLED may be disposed in the display area DA, and the second touch electrode 430 may have a mesh structure that surrounds each of the organic light-emitting diodes OLED.

According to some embodiments, an insulating layer may be additionally interposed between the first touch electrode 410 and the second inorganic encapsulation layer 330. The insulating layer may include at least one inorganic insulating material selected from silicon oxide (SiOₓ), silicon nitride (SiNₓ), and silicon oxynitride (SiOₓN_{y}).

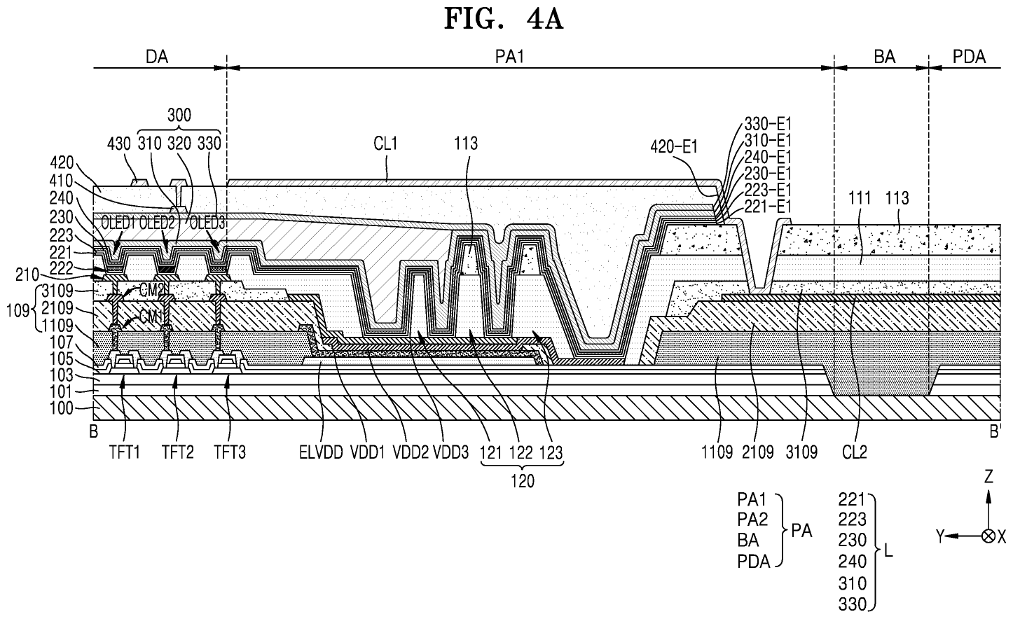

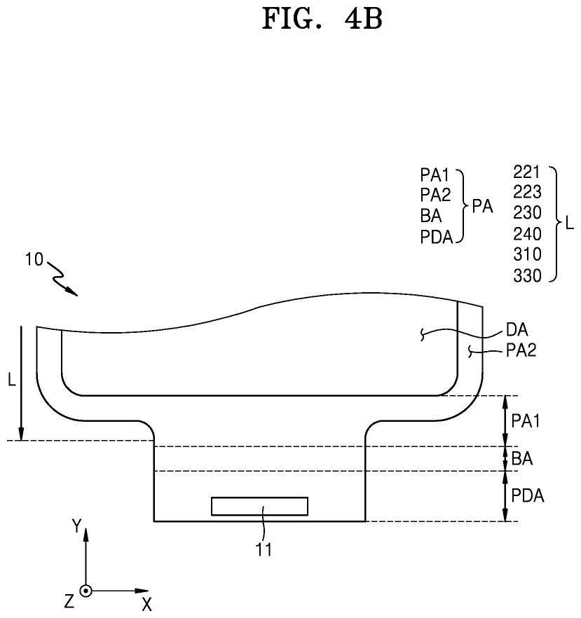

FIG. 4A is a schematic cross-sectional view of a portion of a display apparatus according to an embodiment. FIG. 4A may correspond to a cross-section of an embodiment of the display apparatus 1 taken along line B-B′ of FIG. 1.

Referring to FIG. 4A, organic light-emitting diodes and their corresponding thin-film transistors may be disposed in the display area DA. For example, first, second, and third organic light-emitting diodes OLED1, OLED2, and OLED3 and first, second, and third thin-film transistors TFT1, TFT2, and TFT3 corresponding thereto may be disposed in the display area DA. The first, second, and third organic light-emitting diodes OLED1, OLED2, and OLED3 may emit light beams of different colors, respectively. According to an embodiment, the first organic light-emitting diode OLED1 may emit red light, the second organic light-emitting diodes OLED2 may emit green light, and the third organic light-emitting diodes OLED3 may emit blue light.

The first peripheral area PA1 may be disposed on a negative Y-axis direction side of the display area DA. The bending area BA may be disposed on a negative Y-axis direction side of the first peripheral area PA1. The pad area PDA may be disposed on a negative Y-axis direction side of the bending area BA.

The barrier layer 101, the buffer layer 103, the gate insulating layer 105, and the interlayer insulating layer 107 may be disposed in the first peripheral area PA1 and the pad area PDA. For example, the barrier layer 101, the buffer layer 103, the gate insulating layer 105, and the interlayer insulating layer 107 may include an opening that overlaps the bending area BA. For example, the barrier layer 101, the buffer layer 103, the gate insulating layer 105, and the interlayer insulating layer 107 may not be disposed in the bending area BA. As the barrier layer 101, the buffer layer 103, the gate insulating layer 105, and the interlayer insulating layer 107 are not disposed in the bending area BA, a display panel may be smoothly bent in the bending area BA.

The first, second, and third organic insulating layers 1109, 2109, and 3109 and the bank layer 111 may be disposed in the first peripheral area PA1, the bending area BA, and the pad area PDA. A spacer layer 113 may be additionally disposed on the bank layer 111 in the first peripheral area PA1, the bending area BA, and the pad area PDA.

A driving voltage line ELVDD may be disposed on the interlayer insulating layer 107 in the first peripheral area PA1. A first driving voltage supply line VDD1 may be disposed on the driving voltage line ELVDD. The first driving voltage supply line VDD1 and the first connection metal CM1 may be formed as the same layer or may be formed on the same layer. According to an embodiment, the first driving voltage supply line VDD1 may be formed by the same process as a process for forming the first connection metal CM1. A second driving voltage supply line VDD2 may be disposed on the first driving voltage supply line VDD1. The second driving voltage supply line VDD2 and the second connection metal CM2 may be formed as the same layer or may be formed on the same layer. According to an embodiment, the second driving voltage supply line VDD2 may be formed by the same process as a process for forming the second connection metal CM2. A third driving voltage supply line VDD3 may be disposed on the second driving voltage supply line VDD2. The third driving voltage supply line VDD3 and the subpixel electrode 210 may be formed as the same layer or may be formed on the same layer. According to an embodiment, the third driving voltage supply line VDD3 may be formed by the same process as a process for forming the subpixel electrode 210.

Walls (e.g., partition walls) 120 may be arranged in the first peripheral area PA1. For example, first, second, and third walls (e.g., first, second, and third partition walls) 121, 122, and 123 may be sequentially arranged in the negative Y-axis direction in the first peripheral area PA1. The first wall 121 may be disposed on the third driving voltage supply line VDD3. The first wall 121 and the bank layer 111 may be formed as the same layer or may be formed on the same layer. The second wall 122 may be disposed on the third driving voltage supply line VDD3. The second wall 122 and the bank layer 111 may include the same layer. The second wall 122 and the spacer layer 113 may include the same layer. The third wall 123 may be disposed on the second driving voltage supply line VDD2. The third wall 123 and the bank layer 111 may include the same layer. The third wall 123 and the spacer layer 113 may include the same layer. The first, second, and third walls 121, 122, and 123 may block an organic material from flowing toward the edge portion of the substrate 100 in case that the organic encapsulation layer 320 of the encapsulation layer 300 is formed, thereby preventing formation of an edge tail (or edge end portion) of the organic encapsulation layer 320. Although the formation of three walls 120 will now be shown and described, embodiments are not limited thereto.

Each of the first and second common layers 221 and 223, the opposite electrode 230, the capping layer 240, and the first and second inorganic encapsulation layers 310 and 330 may extend into the first peripheral area PA1. Accordingly, the first and second common layers 221 and 223, the opposite electrode 230, the capping layer 240, and the first and second inorganic encapsulation layers 310 and 330 may cover the first, second, and third walls 121, 122, and 123.

Respective edge portions of the first and second common layers 221 and 223, the opposite electrode 230, the capping layer 240, and the first and second inorganic encapsulation layers 310 and 330 may be disposed on the spacer layer 113 in the first peripheral area PA1. For example, a first edge portion 221-E1 of the first common layer 221, a first edge portion 223-E1 of the second common layer 223, a first edge portion 230-E1 of the opposite electrode 230, a first edge portion 240-E1 of the capping layer 240, a first edge portion 310-E1 of the first inorganic encapsulation layer 310, and a first edge portion 330-E1 of the second inorganic encapsulation layer 330 may be disposed in the first peripheral area PA1, and may be disposed on the spacer layer 113.

According to embodiments, the first edge portion 310-E1 of the first inorganic encapsulation layer 310 and the first edge portion 330-E1 of the second inorganic encapsulation layer 330 may be on the same plane (or may be coplanar with each other). According to some embodiments, the first edge portion 230-E1 of the opposite electrode 230 and the first edge portion 240-E1 of the capping layer 240 may be on the same plane (or may be coplanar with each other). According to some embodiments, the first edge portion 221-E1 of the first common layer 221 and the first edge portion 223-E1 of the second common layer 223 may be on the same plane (or may be coplanar with each other). According to some embodiments, the first edge portion 230-E1 of the opposite electrode 230, the first edge portion 310-E1 of the first inorganic encapsulation layer 310, and the first edge portion 330-E1 of the capping layer 240 may be on the same plane (or may be coplanar with each other). According to some embodiments, the first edge portion 221-E1 of the first common layer 221, the first edge portion 223-E1 of the second common layer 223, the first edge portion 230-E1 of the opposite electrode 230, the first edge portion 240-E1 of the capping layer 240, the first edge portion 310-E1 of the first inorganic encapsulation layer 310, and the first edge portion 330-E1 of the second inorganic encapsulation layer 330 may be on the same plane (or may be coplanar with each other).

The touch insulating layer 420 may extend to the first peripheral area PA1. The first edge portion 420-E1 of the touch insulating layer 420 may be disposed in the first peripheral area PA1 and may be disposed on the spacer layer 113. The first edge portion 420-E1 of the touch insulating layer 420 may be disposed in the negative Y-axis direction more than the first edge portion 221-E1 of the first common layer 221, the first edge portion 223-E1 of the second common layer 223, the first edge portion 230-E1 of the opposite electrode 230, the first edge portion 240-E1 of the capping layer 240, the first edge portion 310-E1 of the first inorganic encapsulation layer 310, and the first edge portion 330-E1 of the second inorganic encapsulation layer 330. For example, the touch insulating layer 420 may cover the first edge portion 221-E1 of the first common layer 221, the first edge portion 223-E1 of the second common layer 223, the first edge portion 230-E1 of the opposite electrode 230, the first edge portion 240-E1 of the capping layer 240, the first edge portion 310-E1 of the first inorganic encapsulation layer 310, and the first edge portion 330-E1 of the second inorganic encapsulation layer 330 in the first peripheral area PA1.

A first connection line CL1 may be disposed in the first peripheral area PA1 and may be disposed on the touch insulating layer 420. The first connection line CL1 and the second touch electrode 430 may be formed as the same layer or may be formed on the same layer. According to an embodiment, the first connection line CL1 may be formed by the same process for the process for forming the second touch electrode 430.

A second connection line CL2 may overlap the first peripheral area PA1 and may extend to the bending area BA and the pad area PDA. According to an embodiment, the second connection line CL2 may be interposed between the second organic insulating layer 2109 and the third organic insulating layer 3109. For example, the second connection line CL2, the subpixel electrode 210, and the third driving voltage supply line VDD3 may be formed as the same layer or may be formed on the same layer. The second connection line CL2, the subpixel electrode 210, and the third driving voltage supply line VDD3 may be formed by the same process. According to another embodiment, the second connection line CL2 may be interposed between the first organic insulating layer 1109 and the second organic insulating layer 2109. The second connection line CL2 may partially overlap the touch insulating layer 420 and may partially overlap the first connection line CL1.

The spacer layer 113, the bank layer 111, and the third organic insulating layer 3109 may include an opening that overlaps the second connection line CL2. According to another embodiment, in case that the second connection line CL2 is interposed between the first and second organic insulating layers 1109 and 2109, the spacer layer 113, the bank layer 111, the third organic insulating layer 3109, and the second organic insulating layer 2109 may include an opening that overlaps the second connection line CL2. A portion of the first connection line CL1 may be disposed in the opening and may be in contact with (e.g., in direct contact with) the second connection line CL2. Accordingly, the first connection line CLI and the second connection line CL2 may be connected (e.g., electrically connected) to each other, and power may be supplied from the pad area PDA to the display area DA. For example, respective portions of the first and second common layers 221 and 223, the opposite electrode 230, the capping layer 240, the first and second inorganic encapsulation layers 310 and 330, and the touch insulating layer 420 may be removed so that the first and second connection lines CL1 and CL2 may be connected (e.g., electrically connected) to each other.

FIG. 4B is a schematic plan view of the embodiment shown in FIG. 4A.

Referring to FIG. 4B, in case that the first common layer 221, the second common layer 223, the opposite electrode 230, the capping layer 240, the first inorganic encapsulation layer 310, and the second inorganic encapsulation layer 330 are defined as a main layer L, the main layer L may be disposed in the display area DA and the second peripheral area PA2, may be disposed on a portion of the first peripheral area PA1, and may not be disposed in the bending area BA and the pad area PDA. For example, a boundary or edge portion of the main layer L may be disposed in the first peripheral area PA1. FIG. 4B shows that the boundary or edge portion of the main layer L is disposed on a negative Y-axis direction side more than an area of the display panel where the positive X-axis direction and the negative X-axis direction length of the display panel is reduced. However, embodiments are not limited thereto.

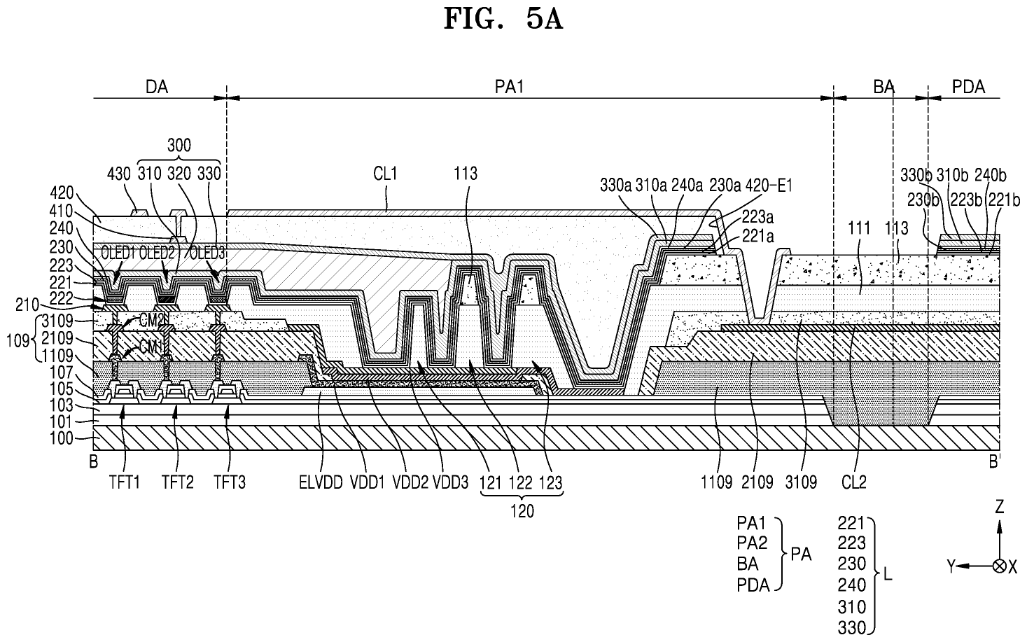

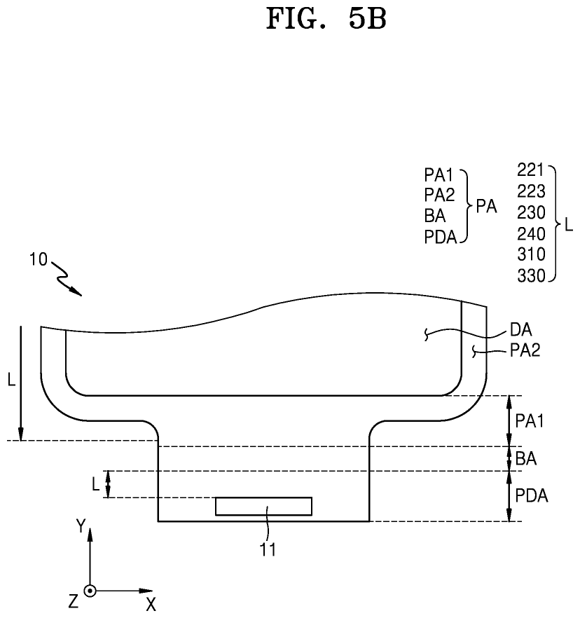

FIG. 5A is a schematic cross-sectional view of a portion of a display apparatus according to another embodiment. FIG. 5A may correspond to a cross-section of another embodiment of the display apparatus 1 taken along line B-B′ of FIG. 1.

Referring to FIG. 5A, respective portions of the first common layer 221, the second common layer 223, the opposite electrode 230, the capping layer 240, the first inorganic encapsulation layer 310, and the second inorganic encapsulation layer 330 may be disposed in the display area DA and the first peripheral area PA1, and respective other portions thereof may be disposed in the pad area PDA.

According to an embodiment, the first common layer 221 may include a 1-1 common layer 221a overlapping the display area DA and the first peripheral area PA1, and a 1-2 common layer 221b overlapping the pad area PDA. The second common layer 223 may include a 2-1 common layer 223a overlapping the display area DA and the first peripheral area PA1, and a 2-2 common layer 223b overlapping the pad area PDA. The opposite electrode 230 may include a first opposite electrode 230a overlapping the display area DA and the first peripheral area PA1, and a second opposite electrode 230b overlapping the pad area PDA. The capping layer 240 may include a first capping layer 240a overlapping the display area DA and the first peripheral area PA1, and a second capping layer 240b overlapping the pad area PDA. The first inorganic encapsulation layer 310 may include a 1-1 inorganic encapsulation layer 310a overlapping the display area DA and the first peripheral area PA1, and a 1-2 inorganic encapsulation layer 310b overlapping the pad area PDA. The second inorganic encapsulation layer 330 may include a 2-1 inorganic encapsulation layer 330a overlapping the display area DA and the first peripheral area PA1, and a 2-2 inorganic encapsulation layer 330b overlapping the pad area PDA.

The 1-2 common layer 221b, the 2-2 common layer 223b, the second opposite electrode 230b, the second capping layer 240b, the 1-2 inorganic encapsulation layer 310b, and the 2-2 inorganic encapsulation layer 330b may overlap the pad area PDA and may be disposed on the spacer layer 113.

The 1-1 common layer 221a and the 1-2 common layer 221b may be spaced apart from each other with the bending area BA between the 1-1 common layer 221a and the 1-2 common layer 221b. The 2-1 common layer 223a and the 2-2 common layer 223b may be spaced apart from each other with the bending area BA between the 2-1 common layer 223a and the 2-2 common layer 223b. The first opposite electrode 230a and the second opposite electrode 230b may be spaced apart from each other with the bending area BA between the first opposite electrode 230a and the second opposite electrode 230b. The first capping layer 240a and the second capping layer 240b may be spaced apart from each other with the bending area BA between the first capping layer 240a and the second capping layer 240b. The 1-1 inorganic encapsulation layer 310a and the 1-2 inorganic encapsulation layer 310b may be spaced apart from each other with the bending area BA between the 1-1 inorganic encapsulation layer 310a and the 1-2 inorganic encapsulation layer 310b. The 2-1 inorganic encapsulation layer 330a and the 2-2 inorganic encapsulation layer 330b may be spaced apart from each other with the bending area BA between the 2-1 inorganic encapsulation layer 330a and the 2-2 inorganic encapsulation layer 330b.

Respective edge portions of the 1-2 common layer 221b, the 2-2 common layer 223b, the second opposite electrode 230b, the second capping layer 240b, the 1-2 inorganic encapsulation layer 310b, and the 2-2 inorganic encapsulation layer 330b may be disposed in the pad area PDA. Respective edge portions of the 1-1 common layer 221a, the 2-1 common layer 223a, the first opposite electrode 230a, the first capping layer 240a, the 1-1 inorganic encapsulation layer 310a, and the 2-1 inorganic encapsulation layer 330a may be disposed in the first peripheral area PA1.

For example, the first common layer 221, the second common layer 223, the opposite electrode 230, the capping layer 240, the first inorganic encapsulation layer 310, and the second inorganic encapsulation layer 330 may include an opening that overlaps the bending area BA and a portion of the first peripheral area PA1.

FIG. 5B is a schematic plan view of the embodiment shown in FIG. 5A.

Referring to FIG. 5B, the main layer L may be disposed in the pad area PDA in addition to the display area DA and a portion of the first peripheral area PA1. For example, referring back to FIG. 5A, the main layer L overlapping the display area DA and the first peripheral area PA1 may be the 1-1 common layer 221a, the 2-1 common layer 223a, the first opposite electrode 230a, the first capping layer 240a, the 1-1 inorganic encapsulation layer 310a, and the 2-1 inorganic encapsulation layer 330a. Referring back to FIG. 5A, the main layer L overlapping the pad area PDA may be the 1-2 common layer 221b, the 2-2 common layer 223b, the second opposite electrode 230b, the second capping layer 240b, the 1-2 inorganic encapsulation layer 310b, and the 2-2 inorganic encapsulation layer 330b.

As shown in FIG. FIG. 5B, the main layer L may be disposed between the bending area BA and the display driving unit 11. For example, the main layer L may not cover the display driving unit 11.

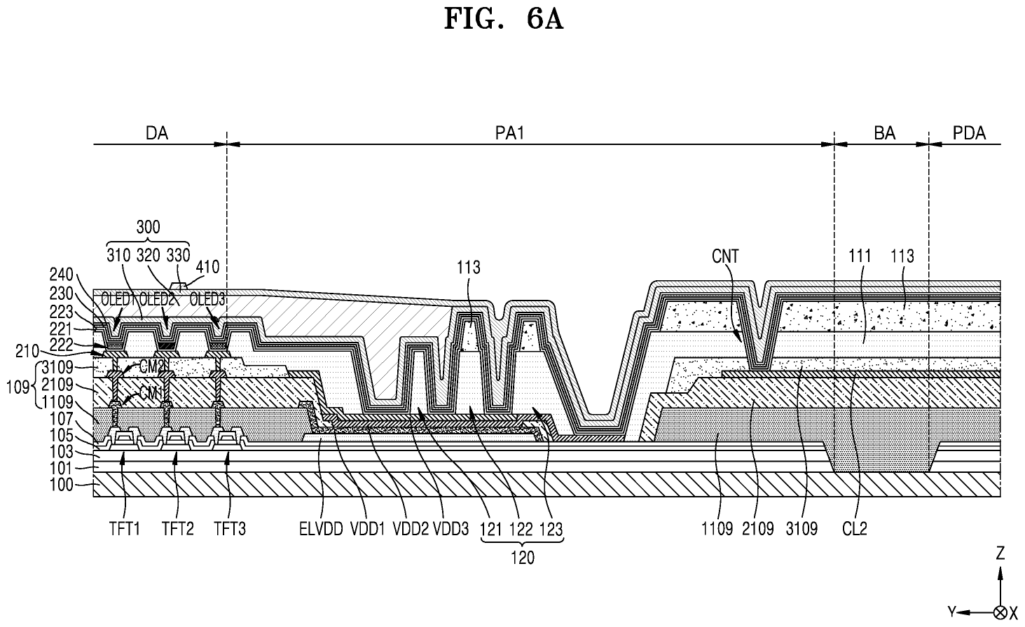

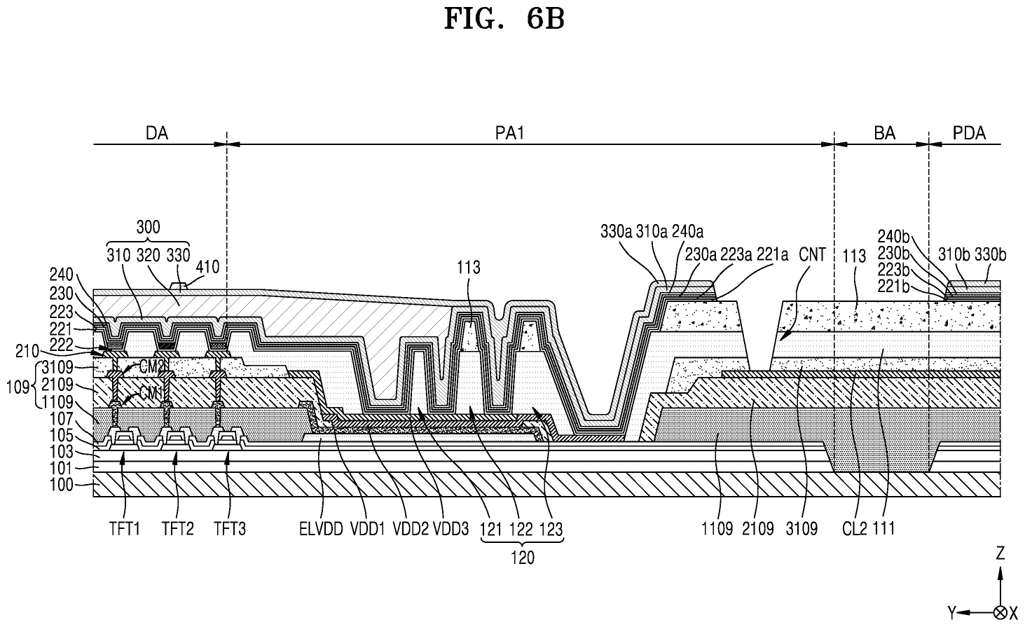

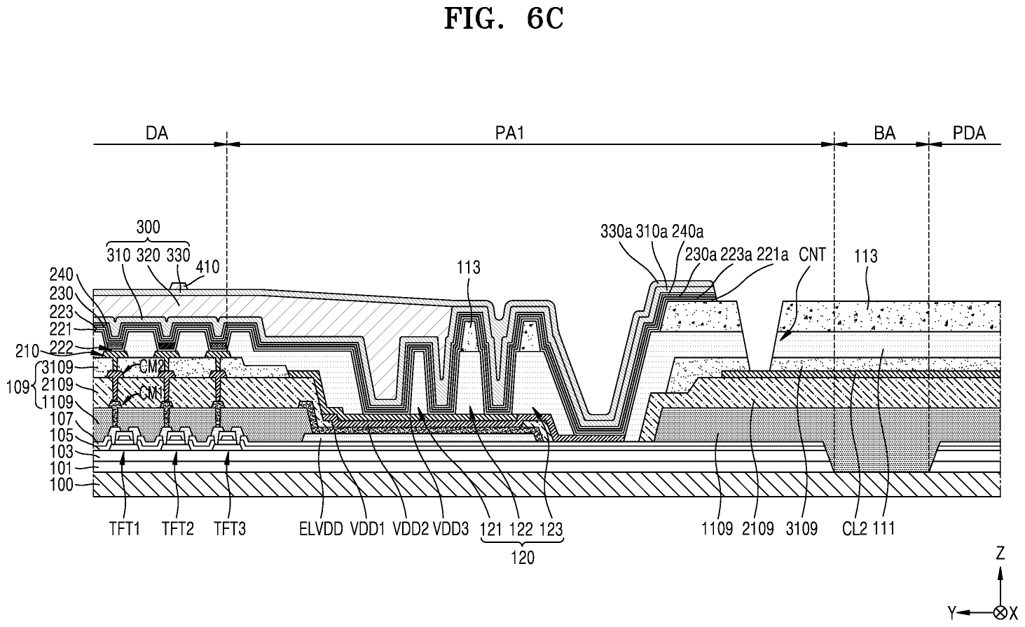

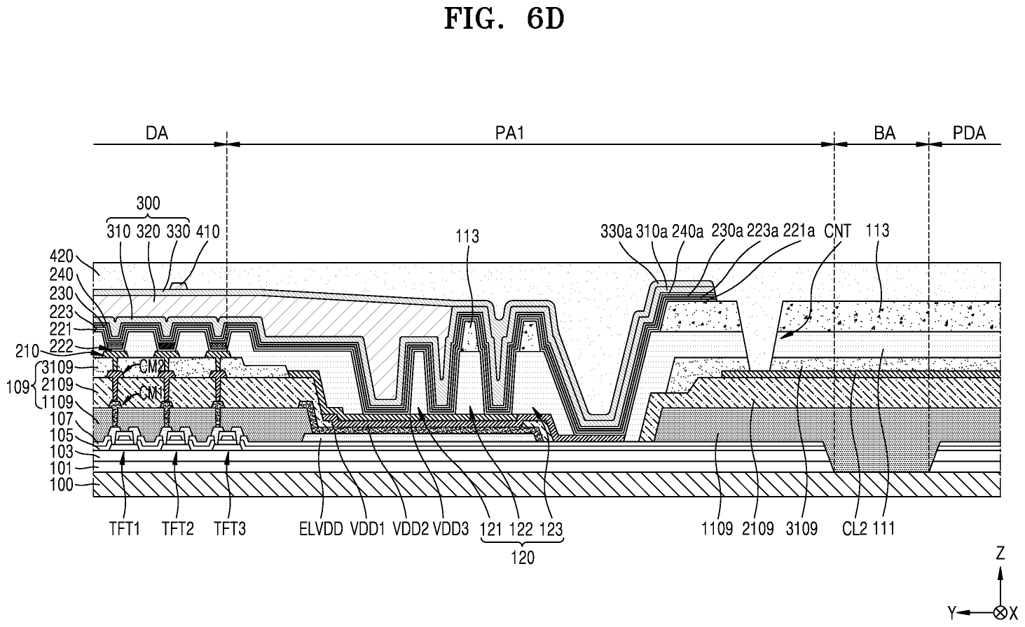

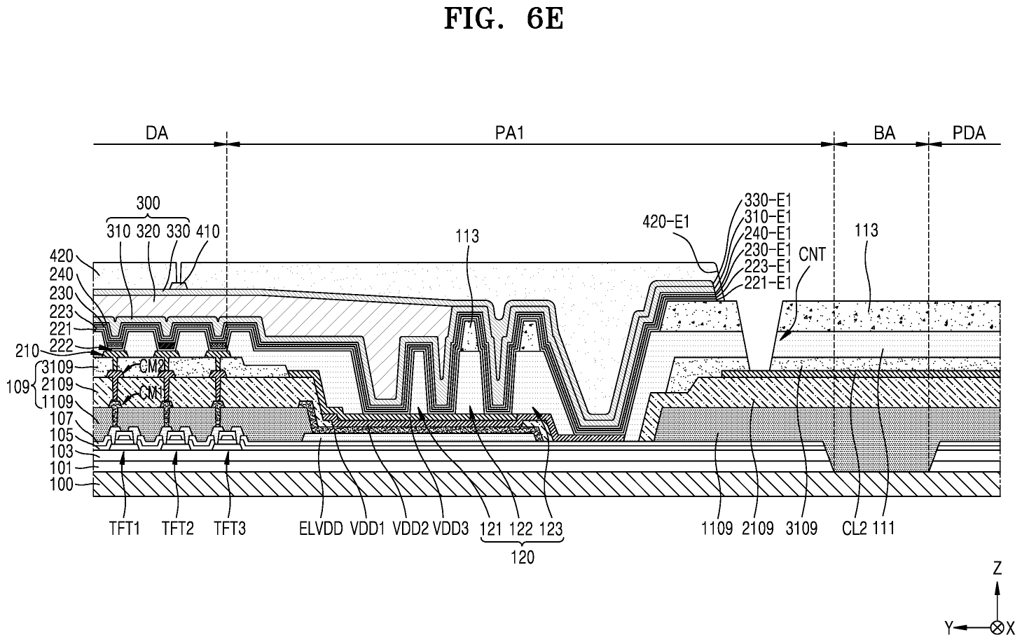

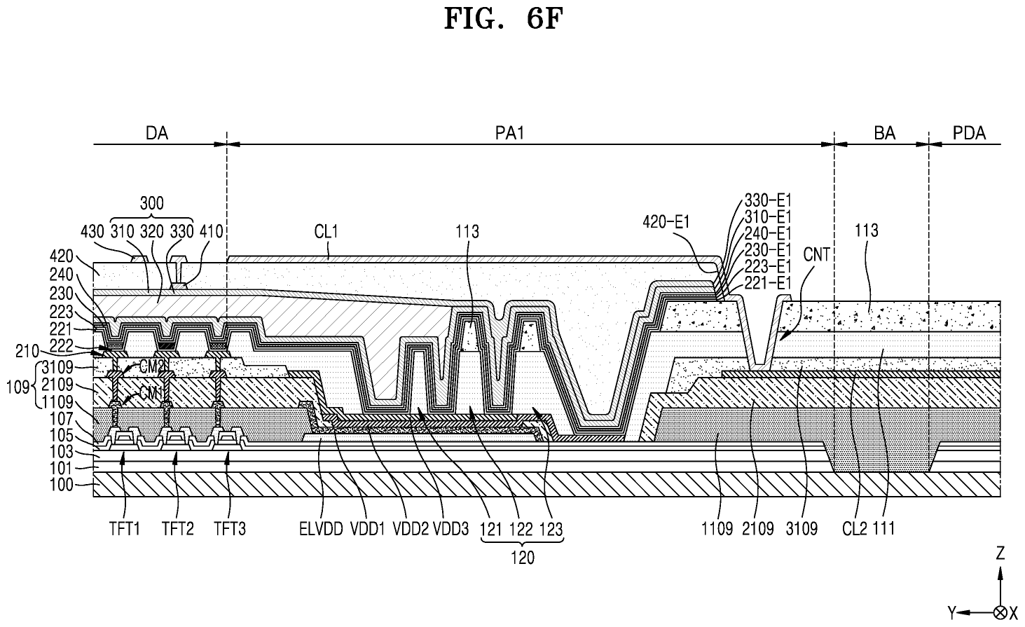

FIGS. 6A through 6F are schematic cross-sectional views illustrating a method of manufacturing a display apparatus, according to an embodiment.

Referring to FIG. 6A, the first common layer 221, the second common layer 223, the opposite electrode 230, the capping layer 240, the first inorganic encapsulation layer 310, and the second inorganic encapsulation layer 330 may include an opening that overlaps the bending area BA and a portion of the first peripheral area PA1. For example, the first common layer 221, the second common layer 223, the opposite electrode 230, the capping layer 240, the first inorganic encapsulation layer 310, and the second inorganic encapsulation layer 330 may be formed on the entire upper surface of the display apparatus.

The third organic insulating layer 3109, the bank layer 111, and the spacer layer 113 may be opened in the first peripheral area PA1. Such a connection opening CNT may be at least partially filled with the first common layer 221, the second common layer 223, the opposite electrode 230, the capping layer 240, the first inorganic encapsulation layer 310, and the second inorganic encapsulation layer 330.

The first touch electrode 410 may be formed on the second inorganic encapsulation layer 330. The second connection line CL2 may be interposed between the second organic insulating layer 2109 and the third organic insulating layer 3109.

Referring to FIG. 6B, the first common layer 221, the second common layer 223, the opposite electrode 230, the capping layer 240, the first inorganic encapsulation layer 310, and the second inorganic encapsulation layer 330 may be removed in the bending area BA, a portion of the first peripheral area PA1, and a portion of the pad area PDA.

The first common layer 221 may be divided into the 1-1 common layer 221a and the 1-2 common layer 221b. The 1-1 common layer 221a may overlap the display area DA and the first peripheral area PA1, and its edge portion may be disposed in the first peripheral area PA1. The 1-2 common layer 221b may overlap the pad area PDA, and its edge portion may be disposed in the pad area PDA.

The second common layer 223 may be divided into the 2-1 common layer 223a and the 2-2 common layer 223b. The 2-1 common layer 223a may overlap the display area DA and the first peripheral area PA1, and its edge portion may be disposed in the first peripheral area PA1. The 2-2 common layer 223b may overlap the pad area PDA, and its edge portion may be disposed in the pad area PDA.

The opposite electrode 230 may be divided into the first opposite electrode 230a and the second opposite electrode 230b. The first opposite electrode 230a may overlap the display area DA and the first peripheral area PA1, and its edge portion may be disposed in the first peripheral area PA1. The second opposite electrode 230b may overlap the pad area PDA, and its edge portion may be disposed in the pad area PDA.

The capping layer 240 may be divided into the first capping layer 240a and the second capping layer 240b. The first capping layer 240a may overlap the display area DA and the first peripheral area PA1, and its edge portion may be disposed in the first peripheral area PA1. The second capping layer 240b may overlap the pad area PDA, and its edge portion may be disposed in the pad area PDA.

The first inorganic encapsulation layer 310 may be divided into the 1-1 inorganic encapsulation layer 310a and the 1-2 inorganic encapsulation layer 310b. The 1-1 inorganic encapsulation layer 310a may overlap the display area DA and the first peripheral area PA1, and its edge portion may be disposed in the first peripheral area PA1. The 1-2 inorganic encapsulation layer 310b may overlap the pad area PDA, and its edge portion may be disposed in the pad area PDA.

The second inorganic encapsulation layer 330 may be divided into the 2-1 inorganic encapsulation layer 330a and the 2-2 inorganic encapsulation layer 330b. The 2-1 inorganic encapsulation layer 330a may overlap the display area DA and the first peripheral area PA1, and its edge portion may be disposed in the first peripheral area PA1. The 2-2 inorganic encapsulation layer 330b may overlap the pad area PDA, and its edge portion may be disposed in the pad area PDA.

The 1-1 common layer 221a, the 2-1 common layer 223a, the first opposite electrode 230a, the first capping layer 240a, the 1-1 inorganic encapsulation layer 310a, and the 2-1 inorganic encapsulation layer 330a may be disposed on a positive Y-axis side more than the connection opening CNT. Respective edge portions (for example, first edge portions) of the 1-1 common layer 221a, the 2-1 common layer 223a, the first opposite electrode 230a, the first capping layer 240a, the 1-1 inorganic encapsulation layer 310a, and the 2-1 inorganic encapsulation layer 330a that face the connection opening CNT may be disposed on the same plane (or may be coplanar with each other).

A process of removing respective portions of the first and second common layers 221 and 223 may include a wet etching process. A process of removing respective portions of the opposite electrode 230, the capping layer 240, the first inorganic encapsulation layer 310, and the second inorganic encapsulation layer 330 may include a dry etching process.

Referring to FIGS. 6B and 6C, the 1-2 common layer 221b, the 2-2 common layer 223b, the second opposite electrode 230b, the second capping layer 240b, the 1-2 inorganic encapsulation layer 310b, and the 2-2 inorganic encapsulation layer 330b may be removed.

Accordingly, the first common layer 221, the second common layer 223, the opposite electrode 230, the capping layer 240, the first inorganic encapsulation layer 310, and the second inorganic encapsulation layer 330 may overlap the display area DA and the first peripheral area PA1, and respective edge portions thereof may be disposed in the first peripheral area PA1. For example, the first common layer 221, the second common layer 223, the opposite electrode 230, the capping layer 240, the first inorganic encapsulation layer 310, and the second inorganic encapsulation layer 330 may be disposed on the positive Y-axis side more than the connection opening CNT.

Referring to FIG. 6D, the touch insulating layer 420 may be formed. The touch insulating layer 420 may be formed on the entire upper surface of the display apparatus, and may cover the first touch electrode 410, the second inorganic encapsulation layer 330, and the spacer layer 113. The connection opening CNT may be at least partially (e.g., completely) filled with the touch insulating layer 420.

Referring to FIG. 6E, a portion of the touch insulating layer 420 may be removed from the pad area PDA, the bending area BA, and the first peripheral area PA1.

For example, the connection opening CNT may be opened again, and the first edge portion 420-E1 of the touch insulating layer 420 may be disposed on a positive Y-axis direction side of the connection opening CNT.

The touch insulating layer 420 may cover the first common layer 221, the second common layer 223, the opposite electrode 230, the capping layer 240, the first inorganic encapsulation layer 310, and the second inorganic encapsulation layer 330. For example, the touch insulating layer 420 may cover the first edge portion 221-E1 of the first common layer 221, the first edge portion 223-E1 of the second common layer 223, the first edge portion 230-E1 of the opposite electrode 230, the first edge portion 240-E1 of the capping layer 240, the first edge portion 310-E1 of the first inorganic encapsulation layer 310, and the first edge portion 330-E1 of the second inorganic encapsulation layer 330. For example, the first edge portion 420-E1 of the touch insulating layer 420 may be disposed between the first edge portion 221-E1 of the first common layer 221, the first edge portion 223-E1 of the second common layer 223, the first edge portion 230-E1 of the opposite electrode 230, the first edge portion 240-E1 of the capping layer 240, the first edge portion 310-E1 of the first inorganic encapsulation layer 310, and the first edge portion 330-E1 of the second inorganic encapsulation layer 330 and the connection opening CNT. For example, the first edge portion 221-E1 of the first common layer 221, the first edge portion 223-E1 of the second common layer 223, the first edge portion 230-E1 of the opposite electrode 230, the first edge portion 240-E1 of the capping layer 240, the first edge portion 310-E1 of the first inorganic encapsulation layer 310, and the first edge portion 330-E1 of the second inorganic encapsulation layer 330 may be disposed on the same plane (or may be coplanar with each other).

Referring to FIG. 6F, the first connection line CL1 may be disposed on the touch insulating layer 420. The first connection line CL1 may cover the first edge portion 420-E1 of the touch insulating layer 420, and a portion thereof may be disposed in the connection opening CNT. The first connection line CL1 may be in contact with (e.g., in direct contact with) the second connection line CL2 in the connection opening CNT. As shown in FIG. 6F, the first connection line CLI may be formed simultaneously with the second touch electrode 430.

According to the manufacturing process shown in FIGS. 6A through 6F, the display apparatus according to the embodiment shown in FIG. 4A may be manufactured.

The operation shown in FIG. 6C is omitted, and, according to the operations of the manufacturing process shown in FIGS. 6A, 6B, 6D, 6E, and 6F, the display apparatus according to the embodiment shown in FIG. 5A may be manufactured.

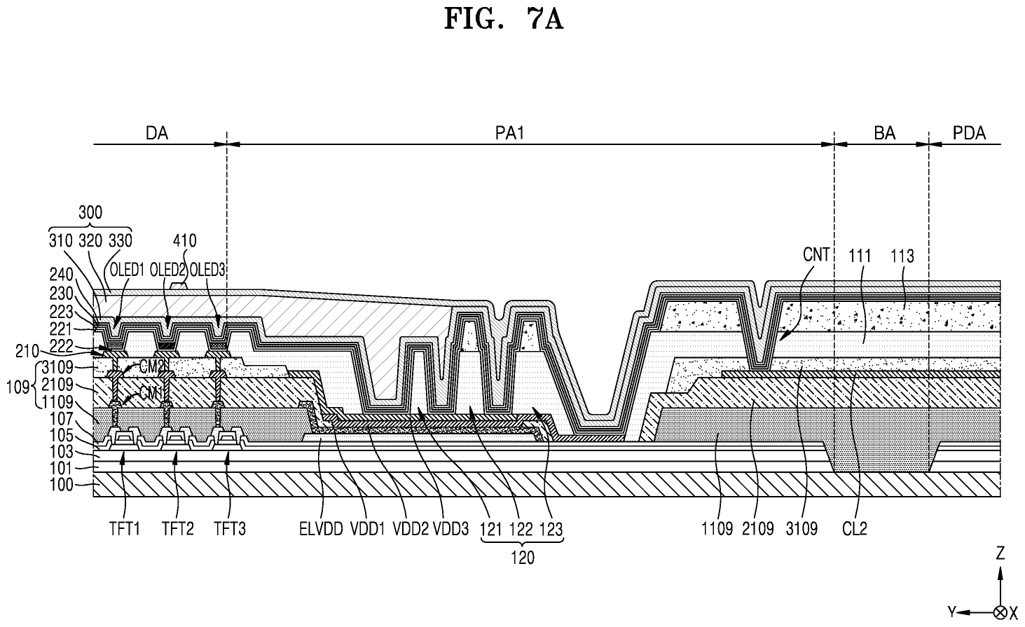

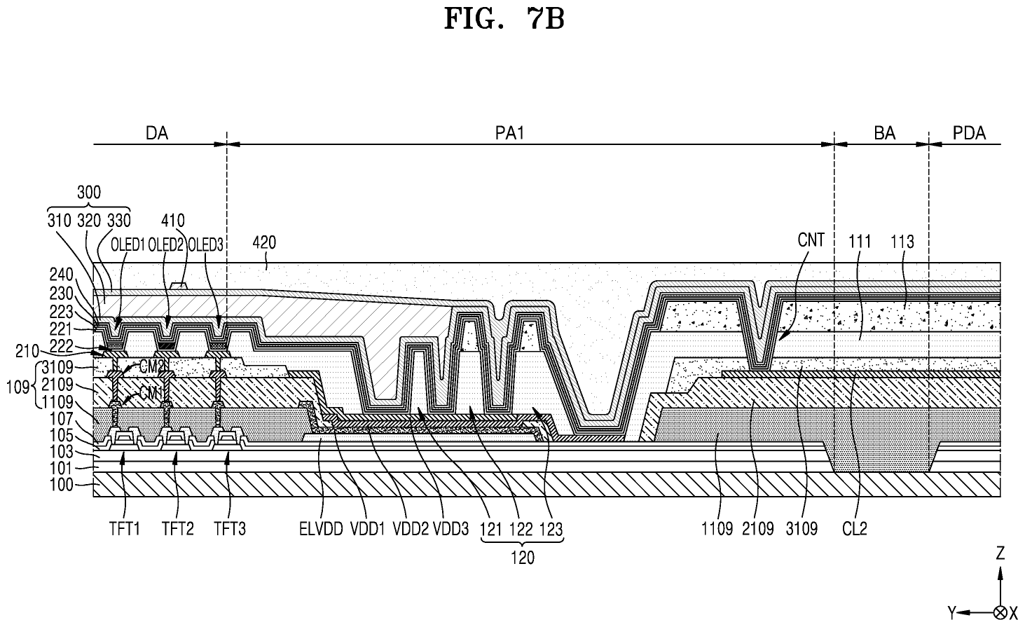

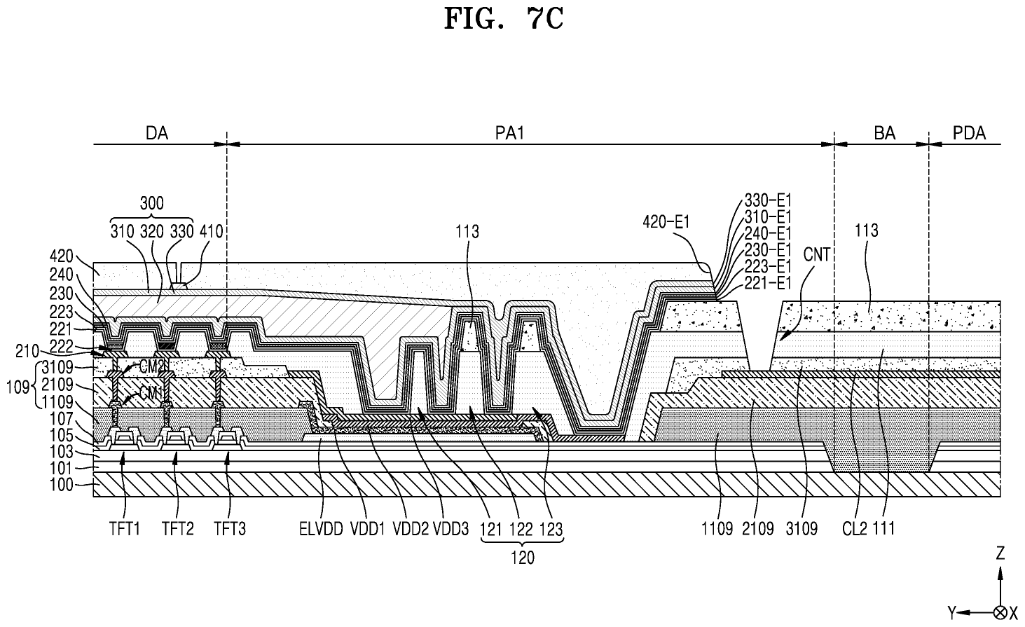

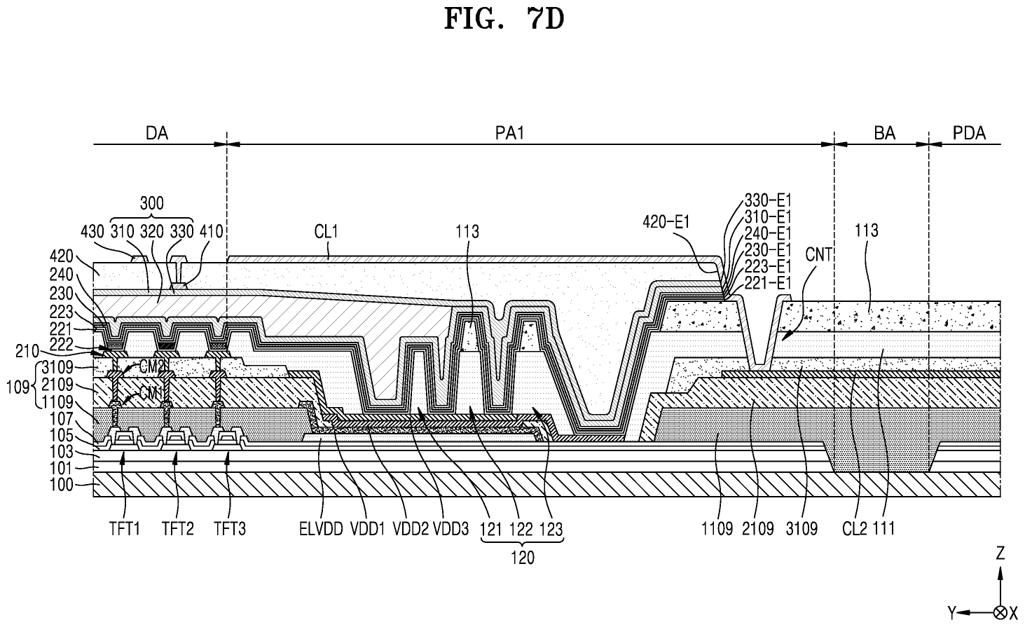

FIGS. 7A through 7D are schematic cross-sectional views illustrating a method of manufacturing a display apparatus, according to another embodiment.

Referring to FIG. 7A, similar to FIG. 6A, the first common layer 221, the second common layer 223, the opposite electrode 230, the capping layer 240, the first inorganic encapsulation layer 310, and the second inorganic encapsulation layer 330 may be formed on the entire upper surface of the display apparatus.

Referring to FIG. 7B, the touch insulating layer 420 may be disposed on the second inorganic encapsulation layer 330. For example, the touch insulating layer 420 may cover the second inorganic encapsulation layer 330.

Referring to FIG. 7C, the touch insulating layer 420, the second inorganic encapsulation layer 330, the first inorganic encapsulation layer 310, the capping layer 240, the opposite electrode 230, the second common layer 223, and the first common layer 221 may be etched. For example, a portion of each layer disposed in the bending area BA and the pad area PDA may be removed (e.g., completely removed), and the connection opening CNT may be opened again.

A process of removing respective portions of the first and second common layers 221 and 223 may include a wet etching process. A process of removing respective portions of the opposite electrode 230, the capping layer 240, the first inorganic encapsulation layer 310, and the second inorganic encapsulation layer 330 may include a dry etching process. A process of removing a portion of the touch insulating layer 420 may include a dry etching process.

The first edge portion 221-E1 of the first common layer 221, the first edge portion 223-E1 of the second common layer 223, the first edge portion 230-E1 of the opposite electrode 230, the first edge portion 240-E1 of the capping layer 240, the first edge portion 310-E1 of the first inorganic encapsulation layer 310, the first edge portion 330-E1 of the second inorganic encapsulation layer 330, and the first edge portion 420-E1 of the touch insulating layer 420 may be disposed on the same plane (or may be coplanar with each other).

Referring to FIG. 7D, the first connection line CL1 may be disposed on the touch insulating layer 420. The first connection line CLI may cover the first edge portion 221-E1 of the first common layer 221, the first edge portion 223-E1 of the second common layer 223, the first edge portion 230-E1 of the opposite electrode 230, the first edge portion 240-E1 of the capping layer 240, the first edge portion 310-E1 of the first inorganic encapsulation layer 310, the first edge portion 330-E1 of the second inorganic encapsulation layer 330, and the first edge portion 420-E1 of the touch insulating layer 420. A portion of the first connection line CL1 may be disposed in the connection opening CNT and may be in contact with (e.g., in direct contact with) the second connection line CL2 in the connection opening CNT. As shown in FIG. 7D, the first connection line CL1 may be formed simultaneously with the second touch electrode 430.

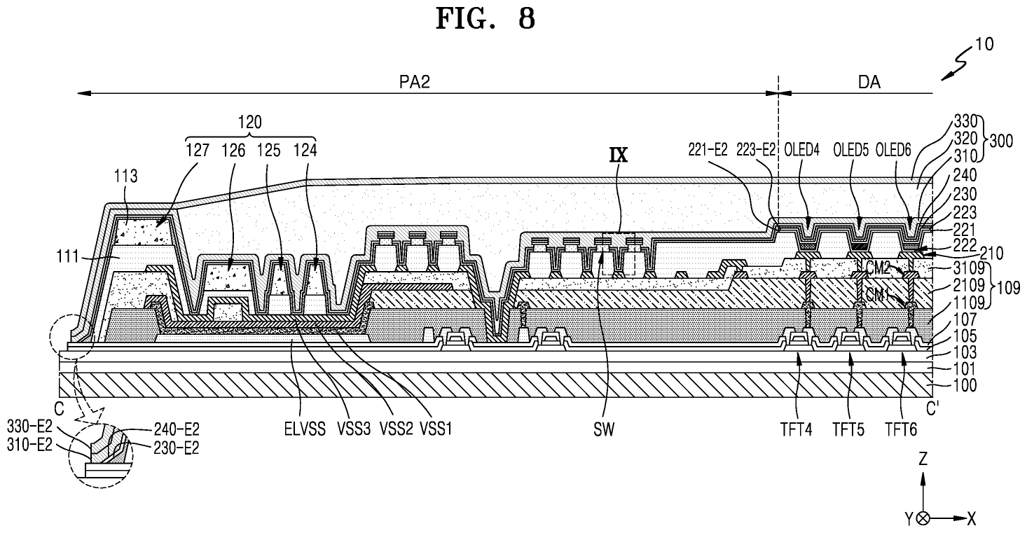

FIG. 8 is a schematic cross-sectional view of a portion of a display apparatus according to an embodiment. FIG. 8 may correspond to a cross-section of an embodiment of the display apparatus 1 taken along line C-C′ of FIG. 1.

Referring to FIG. 8, organic light-emitting diodes and their corresponding thin-film transistors may be disposed in the display area DA. For example, fourth, fifth, and sixth organic light-emitting diodes OLED4, OLED5, and OLED6 and fourth, fifth, and sixth thin-film transistors TFT4, TFT5, and TFT6 corresponding thereto may be disposed in the display area DA. The fourth, fifth, and sixth organic light-emitting diodes OLED4, OLED5, and OLED6 may emit light beams of different colors, respectively. According to an embodiment, the fourth organic light-emitting diode OLED4 may emit red light, the fifth organic light-emitting diodes OLED5 may emit green light, and the sixth organic light-emitting diodes OLED6 may emit blue light.

The second peripheral area PA2 may be disposed on the negative X-axis direction side of the display area DA. Referring to FIG. 1, the second peripheral area PA2 may be disposed on the positive X-axis direction side and the positive Y-axis direction side of the display area DA. However, a case where the second peripheral area PA2 is disposed on the negative X-axis direction side of the display area DA will now be shown and described in detail. However, the features described below are applicable entirely to the second peripheral area PA2 regardless of its location (or position) with respect to the display area DA.

The first, second, and third organic insulating layers 1109, 2109, and 3109 and the bank layer 111 may each extend to the second peripheral area PA2. The spacer layer 113 may be additionally disposed on the bank layer 111 in the second peripheral area PA2.

A common voltage line ELVSS may be disposed on the interlayer insulating layer 107 in the second peripheral area PA2. The first organic insulating layer 1109 may include an opening that overlaps a center portion of the common voltage line ELVSS.

A first common voltage supply line VSS1 may be disposed on the common voltage line ELVSS. The first common voltage supply line VSS1 may contact (e.g., directly contact) the common voltage line ELVSS in the opening of the first organic insulating layer 1109. The first common voltage supply line VSS1 and the first connection metal CM1 may be formed as the same layer or may be formed on the same layer. According to an embodiment, the first driving voltage supply line VDD1 and the first connection metal CM1 may be formed by the same process.

The second common voltage supply line VSS2 may be disposed on the first common voltage supply line VSS1. The second common voltage supply line VSS2 may cover the first common voltage supply line VSS1 together with the second organic insulating layer 2109. The second common voltage supply line VSS2 and the second connection metal CM2 may be formed as the same layer or may be formed on the same layer. According to an embodiment, the second driving voltage supply line VDD2 and the second connection metal CM2 may be formed by the same process.

A third common voltage supply line VSS3 may be disposed on the second common voltage supply line VSS2. The third common voltage supply line VSS3 and the subpixel electrode 210 may be formed as the same layer or may be formed on the same layer. According to an embodiment, the third common voltage supply line VSS3 and the subpixel electrode 210 may be formed by the same process.

Walls 120 may be arranged in the second peripheral area PA2. For example, fourth, fifth, sixth, and seventh walls (e.g., fourth, fifth, sixth, and seventh partition walls) 124, 125, 126, and 127 may be sequentially arranged in the negative X-axis direction in the second peripheral area PA2. The fourth wall 124 may be disposed on the third common voltage supply line VSS3. The fourth wall 124 and the bank layer 111 may include the same layer. The fourth wall 124 and the spacer layer 113 may include the same layer. The fifth wall 125 may be disposed on the third common voltage supply line VSS3. The fifth wall 125 and the bank layer 111 may include the same layer. The fifth wall 125 and the spacer layer 113 may be formed as the same layer. The sixth wall 126 may be disposed on the third organic insulating layer 3109. The sixth wall 126 and the bank layer 111 may include the same layer. The sixth wall 126 and the spacer layer 113 may be formed as the same layer or may be formed on the same layer. A portion of the third common voltage supply line VSS3 may be interposed between the same layer as the third organic insulating layer 3109 of the sixth wall 126 and the same layer as the bank layer 111. The seventh wall 127 may be disposed on the interlayer insulating layer 107. The seventh wall 127, the first organic insulating layer 1109, the third organic insulating layer 3109, the bank layer 111, and the spacer layer 113 may include the same layers. The first common voltage supply line VSS1 and the second common voltage supply line VSS2 may be interposed between the same layer as the third organic insulating layer 1109 of the seventh wall 127 and the same layer as the third organic insulating layer 3109. The third common voltage supply line VSS3 may be interposed between the same layer as the third organic insulating layer 3109 of the seventh wall 127 and the same layer as the bank layer 111.

The fourth, fifth, sixth, and seventh walls 124, 125, 126, and 127 may block an organic material from flowing toward the edge portion of the substrate 100 in case that the organic encapsulation layer 320 of the encapsulation layer 300 is formed, thereby preventing formation of an edge tail (or edge end portion) of the organic encapsulation layer 320. Although the formation of four walls 120 is shown and described with reference to FIG. 8, embodiments are not limited thereto.

Each of the opposite electrode 230, the capping layer 240, and the first and second inorganic encapsulation layers 310 and 330 may extend into the second peripheral area PA2. Accordingly, the opposite electrode 230, the capping layer 240, and the first and second inorganic encapsulation layers 310 and 330 may cover the fourth, fifth, sixth, and seventh walls 124, 125, 126, and 127.

Respective edge portions of the opposite electrode 230, the capping layer 240, the first inorganic encapsulation layer 310, and the second inorganic encapsulation layer 330 disposed in the second peripheral area PA2 may be disposed on an outermost portion of the display panel 10. For example, the second edge portion 230-E2 of the opposite electrode 230, the second edge portion 240-E2 of the capping layer 240, the second edge portion 310-E2 of the first inorganic encapsulation layer 310, and the second edge portion 330-E2 of the second inorganic encapsulation layer 330 may be disposed on a negative X-axis direction side of the seventh wall 127.

According to some embodiments, the first inorganic encapsulation layer 310 may cover the second edge portion 240-E2 of the capping layer 240. According to some embodiments, the capping layer 240 may cover the second edge portion 230-E2 of the opposite electrode 230. According to some embodiments, the second edge portion 310-E2 of the first inorganic encapsulation layer 310 and the second edge portion 330-E2 of the second inorganic encapsulation layer 330 may disposed be on the same plane (or may be coplanar with each other). According to another embodiment, in contrast with FIG. 8, the second edge portion 230-E2 of the opposite electrode 230, the second edge portion 240-E2 of the capping layer 240, the second edge portion 310-E2 of the first inorganic encapsulation layer 310, and the second edge portion 330-E2 of the second inorganic encapsulation layer 330 may be disposed on the same plane (or may be coplanar with each other).

The second edge portion 221-E2 of the first common layer 221 and the second edge portion 223-E2 of the second common layer 223 may be disposed adjacent to the display area DA. For example, the second edge portion 221-E2 of the first common layer 221 and the second edge portion 223-E2 of the second common layer 223 may be interposed between the display area DA and the second edge portion 230-E2 of the opposite electrode 230. According to some embodiments, the second edge portion 221-E2 of the first common layer 221 and the second edge portion 223-E2 of the second common layer 223 may be disposed between the display area DA and a sidewall SW.

Sidewalls SW may be arranged between the display area DA and the fourth wall 124. The sidewalls SW may be arranged on the bank layer 111 and may be spaced apart from each other. The bank layer 111 may include an opening disposed in an area between two sidewalls SW spaced apart from each other. The opposite electrode 230 and the capping layer 240 may be disposed in the opening of the bank layer 111. The opposite electrode 230 and the capping layer 240 may be disposed on each of the sidewalls SW.

The sidewalls SW may include a metal. According to an embodiment, the sidewalls SW may include aluminum (Al) and/or titanium (Ti). The opposite electrode 230 disposed between sidewalls SW may be in contact with (e.g., in direct contact with) the sidewalls SW. Accordingly, sidewalls SW adjacent to each other may be connected (e.g., electrically connected) through the opposite electrode 230 disposed between the sidewalls SW. For example, portions of two opposite electrodes 230 with a sidewall SW between them may be connected (e.g., electrically connected) to each other through the sidewall SW. The opposite electrode 230 may extend in the negative X-axis direction through a structure in which the opposite electrode 230 and the sidewalls SW are repeatedly arranged, and thus may be connected to the third common voltage supply line VSS3. Therefore, the opposite electrode 230 may be connected (e.g., electrically connected) to the common voltage line ELVSS through the sidewalls SW, the third common voltage supply line VSS3, the second common voltage supply line VSS2, and the first common voltage supply line VSS1, and may receive a voltage. The sidewalls SW may prevent the opposite electrode 230 from being provided with a common voltage due to disconnection of the opposite electrode 230 in the second peripheral area PA2 with being arranged.

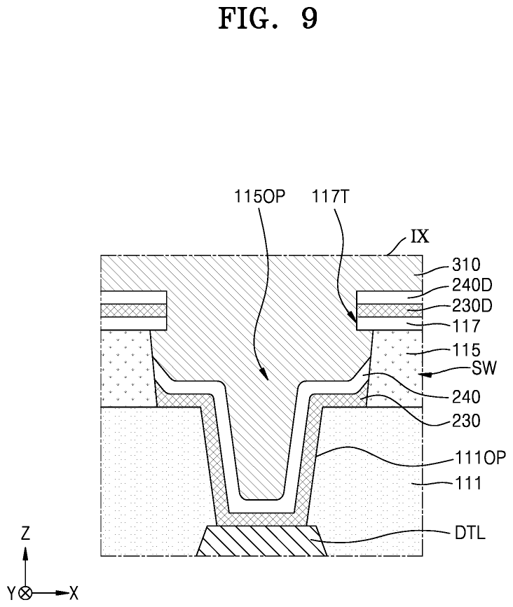

FIG. 9 is a magnified schematic cross-sectional view of region IX of FIG. 8.

Referring to FIG. 9, a sidewall SW may include a first layer 115 in contact with (e.g., in direct contact with) an upper surface of the bank layer 111 and a second layer 117 disposed on the first layer 115. A region between two adjacent sidewalls SW may be defined as a first opening 115OP. A width of the second layer 117 may be greater than that of the first layer 115. According to an embodiment, the second layer 117 may include a tip portion 117T that protrudes toward the first opening 115OP from a lateral surface of the first layer 115 facing the first opening 115OP. For example, the sidewall SW may have an undercut structure.

The bank layer 111 may include a second opening 111OP disposed between the two adjacent sidewalls SW. A center portion of a data line DTL below the second opening 111OP may be exposed through the second opening 111OP. A portion of the opposite electrode 230 may be disposed in the second opening 111OP, and a portion of the opposite electrode 230 may cover a lateral surface of the bank layer 111 facing the second opening 111OP and an upper surface of the bank layer 111. Accordingly, the portion of the opposite electrode 230 may be disposed in the first opening 115OP. In the first opening 115OP, the opposite electrode 230 may contact (e.g., directly contact) each of the two adjacent sidewalls SW. For example, as shown in FIG. 9, the portion of the opposite electrode 230 disposed in the first opening 115OP may be disposed in a diagonal direction with respect to the upper surface of the bank layer 111, and may be in contact with (e.g., in direct contact with) the first layer 115 on the left side (e.g., negative X-axis direction side) and the first layer 115 on the right side (e.g., positive X-axis direction side). Accordingly, the opposite electrode 230 may be connected (e.g., electrically connected) to the sidewall SW on the left side (e.g., negative X-axis direction side) and the sidewall SW on the right side (e.g., positive X-axis direction side).

The capping layer 240 may be disposed on the opposite electrode 230. Accordingly, a portion of the capping layer 240 may be disposed in the second opening 111OP, and the capping layer 240 may cover the opposite electrode 230. A portion of the capping layer 240 may be disposed in the first opening 115OP.

A dummy opposite electrode 230D and a dummy capping layer 240D may be disposed on each of the sidewalls SW. For example, the dummy opposite electrode 230D may be disposed on an upper surface of the second layer 117 of the sidewall SW, and the dummy capping layer 240D may be disposed on the dummy opposite electrode 230D.

The dummy opposite electrode 230D and the opposite electrode 230 may include the same material. The dummy capping layer 240D and the capping layer 240 may include the same material.

The first inorganic encapsulation layer 310 may be disposed to cover the above-described structure. The first inorganic encapsulation layer 310 may fill the first opening 1150OP and the second opening 111OP. The first inorganic encapsulation layer 310 may cover the capping layer 240. The first inorganic encapsulation layer 310 may cover the lateral surface of the first layer 115 facing the first opening 115OP. The first inorganic encapsulation layer 310 may cover the tip portion 117T of the second layer 117, the dummy opposite electrode 230D, and the dummy capping layer 240D.

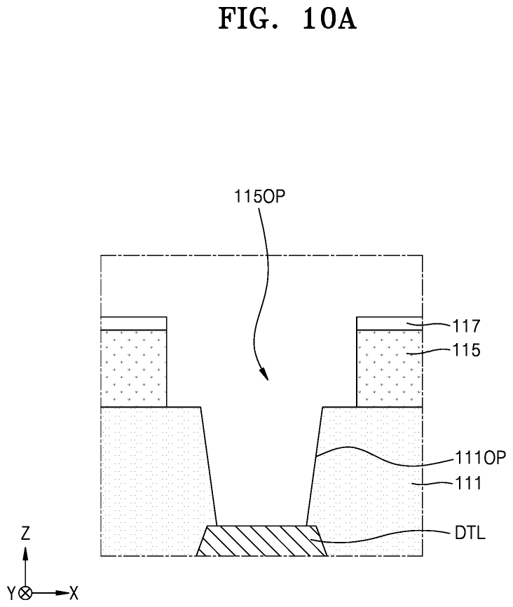

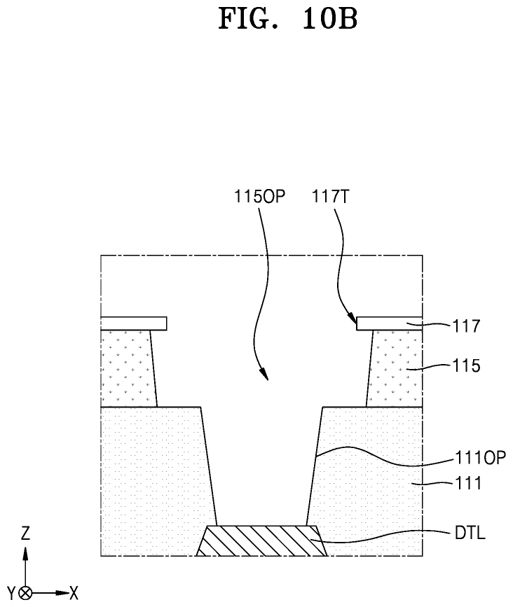

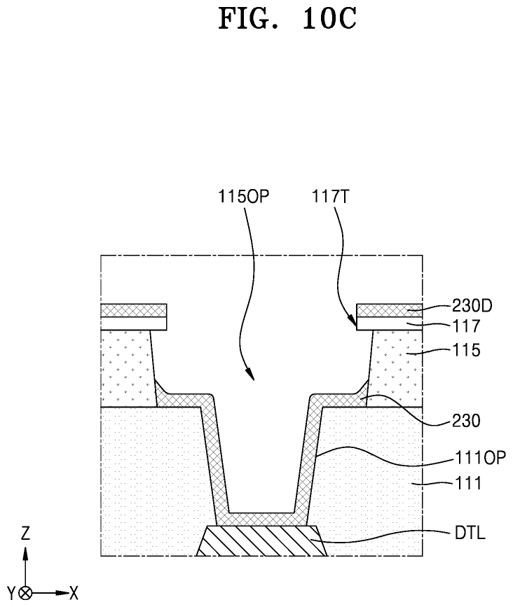

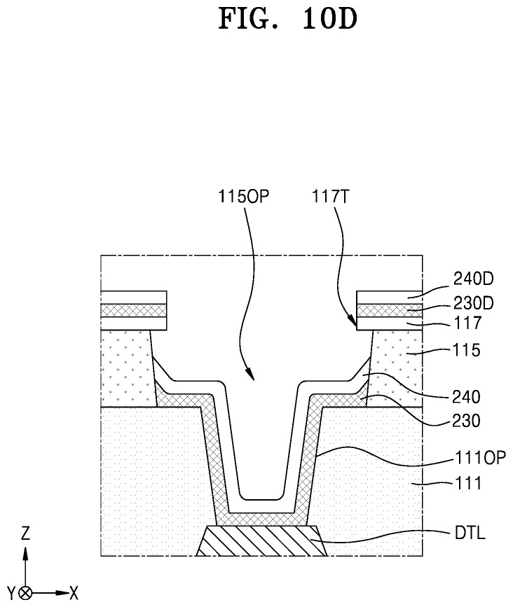

FIGS. 10A through 10D are schematic cross-sectional views illustrating a method of manufacturing the embodiment of FIG. 9.

Referring to FIG. 10A, the bank layer 111 may include the second opening 111OP, and a portion of an upper surface of the data line DTL may be exposed. The first layer 115 and the second layer 117 may be disposed on the bank layer 111 with having an opening. According to some embodiments, the bank layer 111 may be disposed as a whole and etched to thereby form the second opening IILOP. According to some embodiments, the first layer 115 and the second layer 117 may be sequentially disposed on the bank layer 111 and etched to have an opening. For example, a width of the opening (e.g., the first opening 115OP) formed in the first layer 115 may be the same as that of the opening formed in the second layer 117. For example, the respective lateral surfaces of the first and second layers 115 and 117 both facing the first opening 115OP may be disposed on the same plane.

Referring to FIG. 10B, a portion of the first layer 115 may be additionally removed to form an undercut structure. The first layer 115 and the second layer 117 may include materials having different etch selectivities. According to some embodiments, the first layer 115 may include aluminum (Al), and the second layer 117 may include titanium (Ti). According to some embodiments, only the first layer 115 may be additionally removed by being etched using an etchant having an etch selectivity to the first layer 115. Accordingly, the width of the second layer 117 may be greater than that of the first layer 115. In another example, the second layer 117 may include the tip portion 117T that protrudes toward the first opening 115OP from the lateral surface of the first layer 115 facing the first opening 115OP.

Referring to FIG. 10C, the opposite electrode 230 may be disposed on the embodiment shown in FIG. 10B. The opposite electrode 230 may be formed by depositing a material included in the opposite electrode 230. For example, a deposition material disposed in the first opening 115OP and the second opening 111OP may form the opposite electrode 230, and a deposition material disposed on the second layer 117 may form the dummy opposite electrode 230D. Thus, the dummy opposite electrode 230D and the opposite electrode 230 may include the same material. The opposite electrode 230 may be disposed to contact (e.g., directly contact) the lateral surface of the first layer 115 facing the first opening 115OP.

Referring to FIG. 10D, the capping layer 240 may be disposed on the embodiment shown in FIG. 10C. The capping layer 240 may be formed by depositing a material included in the capping layer 240. For example, a deposition material disposed in the first opening 115OP and the second opening 111OP may form the capping layer 240, and a deposition material disposed on the second layer 117 may form the dummy capping layer 240D. Thus, the dummy capping layer 240D and the capping layer 240 may include the same material. Thereafter, the embodiment shown in FIG. 3 may be implemented by disposing the first inorganic encapsulation layer 310 (see FIG. 9) on the capping layer 240 and the dummy capping layer 240D.

According to an embodiment as described above, there is no need to use an open mask in case of forming a common layer, an opposite electrode, a capping layer, and an encapsulation layer of a display apparatus, and thus display apparatuses of various sizes may be freely disposed on the same mother substrate. Accordingly, the percentage of a used area among the area of the mother substrate may increase, and the percentage of the area discarded without being used may be reduced.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display apparatus comprising:
a substrate comprising a display area, a bending area spaced apart from the display area in a first direction, and a first peripheral area disposed between the display area and the bending area;
a plurality of emission layers disposed in the display area;
an opposite electrode disposed on the plurality of emission layers and overlapping the display area and the first peripheral area; and
an encapsulation layer disposed on the opposite electrode and overlapping the display area and the first peripheral area,
wherein a first edge portion of the opposite electrode and a first edge portion of the encapsulation layer are coplanar with each other in the first peripheral area.

2. The display apparatus of claim 1, further comprising:
a common layer disposed above or below the plurality of emission layers.

3. The display apparatus of claim 2, wherein
the common layer overlaps the display area and the first peripheral area, and
a first edge portion of the common layer, the first edge portion of the opposite electrode, and the first edge portion of the encapsulation layer are coplanar with each other in the first peripheral area.

4. The display apparatus of claim 2, wherein
the substrate comprises a second peripheral area partially surrounding the display area,
the opposite electrode and the encapsulation layer overlap the display area and the second peripheral area,
a second edge portion of the opposite electrode and a second edge portion of the encapsulation layer are disposed in the second peripheral area,
the common layer overlaps the display area, and
a second edge portion of the common layer is disposed between the display area and the second edge portion of the opposite electrode.

5. The display apparatus of claim 1, wherein
the substrate further comprises a pad area,
the bending area is disposed between the pad area and the display area,
the opposite electrode comprises a first portion overlapping the first peripheral area and a second portion overlapping the pad area, and
the encapsulation layer comprises a first portion overlapping the first peripheral area and a second portion overlapping the pad area.

6. The display apparatus of claim 5, wherein
the first portion of the opposite electrode and the second portion of the opposite electrode are spaced apart from each other, and
the first portion of the encapsulation layer and the second portion of the encapsulation layer are spaced apart from each other.

7. The display apparatus of claim 1, further comprising:
a touch insulating layer disposed on the encapsulation layer and overlapping the display area and the first peripheral area; and
a first connection line disposed on the touch insulating layer and overlapping the first peripheral area, wherein
a first edge portion of the touch insulating layer is disposed in the first peripheral area, and
the first connection line covers the first edge portion of the touch insulating layer.

8. The display apparatus of claim 7, further comprising:
a second connection line interposed between the substrate and the touch insulating layer and overlapping the first peripheral area and the bending area, wherein
the second connection line overlaps the first edge portion of the touch insulating layer, and
the first connection line and the second connection line are in direct contact with the first peripheral area.

9. The display apparatus of claim 1, wherein
the substrate comprises a second peripheral area partially surrounding the display area, and
the display apparatus further comprises:
a bank layer between the substrate and the opposite electrode; and
a sidewall disposed on the bank layer in the second peripheral area.

10. The display apparatus of claim 9, wherein
the sidewall comprises:
a first layer in direct contact with the bank layer; and
a second layer disposed on the first layer and having a width greater than a width of an upper surface of the first layer, and
the first layer and the second layer comprise materials having different etch selectivities.

11. The display apparatus of claim 1, further comprising:
a capping layer interposed between the opposite electrode and the encapsulation layer and overlapping the display area and the first peripheral area,
wherein a first edge portion of the capping layer, the first edge portion of the opposite electrode, and the first edge portion of the encapsulation layer are coplanar with each other in the first peripheral area.

12. A method of manufacturing a display apparatus, the method comprising:
preparing a substrate comprising a display area, a bending area spaced apart from the display area in a first direction, a pad area disposed in the first direction from the bending area, and a first peripheral area disposed between the display area and the bending area;
arranging a plurality of emission layers spaced apart from each other in the display area;
disposing an opposite electrode on the plurality of emission layers;
disposing an encapsulation layer on the opposite electrode; and
removing a portion of each of the opposite electrode and the encapsulation layer that overlaps the bending area,
wherein, after the removing of the portion of each of the opposite electrode and the encapsulation layer, a first edge portion of the opposite electrode and a first edge portion of the encapsulation layer are coplanar with each other in the first peripheral area.

13. The method of claim 12, wherein
the opposite electrode comprises:
a first portion overlapping the first peripheral area, and
a second portion overlapping the pad area and being spaced apart from the first portion of the opposite electrode,
the encapsulation layer comprises:
a first portion overlapping the first peripheral area, and
a second portion overlapping the pad area and being spaced apart from the first portion of the encapsulation layer, and
the method further comprises removing the second portion of the opposite electrode and the second portion of the encapsulation layer.

14. The method of claim 12, further comprising:
disposing a common layer that is below the opposite electrode and overlaps the plurality of emission layers; and
removing a portion of the common layer that overlaps the bending area,
wherein, after the removing of the portion of the common layer, a first edge portion of the common layer, the first edge portion of the opposite electrode, and the first edge portion of the encapsulation layer are coplanar with each other in the first peripheral area.

15. The method of claim 12, further comprising:
disposing a common layer that is below the opposite electrode and overlaps the plurality of emission layers, wherein
the substrate comprises a second peripheral area partially surrounding the display area,
the opposite electrode and the encapsulation layer overlap the display area and the second peripheral area,
a second edge portion of the opposite electrode and a second edge portion of the encapsulation layer are disposed in the second peripheral area,
the common layer overlaps the display area, and
a second edge portion of the common layer is disposed between the display area and the second edge portion of the opposite electrode.

16. The method of claim 12, further comprising:
disposing a touch insulating layer on the encapsulation layer; and
removing a portion of the touch insulating layer overlapping the bending area and a portion of the touch insulating layer overlapping the pad area,
wherein, after the removing of the portion of the touch insulating layer, a first edge portion of the touch insulating layer is disposed in the first peripheral area.

17. The method of claim 16, further comprising:
disposing a first connection line on the touch insulating layer to cover the first edge portion of the touch insulating layer.

18. The method of claim 12, wherein
the substrate comprises a second peripheral area partially surrounding the display area, and
the method further comprises:
forming a bank layer including a plurality of openings respectively overlapping the plurality of emission layers on the substrate; and
forming a sidewall on the bank layer in the second peripheral area.

19. The method of claim 18, wherein
the forming of the sidewall comprises:
forming a first layer on the bank layer; and
forming a second layer on the first layer, wherein
the first layer and the second layer include materials having different etch selectivities, and
a width of an upper surface of the second layer is greater than a width of the second layer.

20. The method of claim 12, further comprising:
disposing a capping layer interposed between the encapsulation layer and the opposite electrode; and
removing a portion of the capping layer that overlaps the bending area,
wherein, after the removing of the portion of the capping layer, a first edge portion of the capping layer, the first edge portion of the opposite electrode, and the first edge portion of the encapsulation layer are coplanar with each other in the first peripheral area.
